(19) United States
(12) Patent Application Publication
(10) Pub. No.: US 2025/0210584 A1
(43) Pub. Date: Jun. 26, 2025

(54) METHOD OF BONDING LIGHT EMITTING ELEMENT AND METHOD OF MANUFACTURING DISPLAY DEVICE, HAVING THE SAME

(71) Applicant: Samsung Display Co., LTD., Yongin-si (KR)

(72) Inventors: Jae Gwang UM, Yongin-si (KR); Byoung Yong KIM, Yongin-si (KR); Tae Hee LEE, Yongin-si (KR); Moon Won CHANG, Yongin-si (KR)

(73) Assignee: Samsung Display Co., LTD., Yongin-si (KR)

(21) Appl. No.: 18/923,239

(22) Filed: Oct. 22, 2024

(30) Foreign Application Priority Data
Dec. 26, 2023 (KR) 10-2023-0191537

(51) Int. Cl. H01L 23/00; H01L 25/16; H01L 33/62

(52) U.S. Cl. CPC H01L 24/81; H01L 25/167; H01L 2224/81035; H01L 2224/8114; H01L 2224/81191; H01L 2224/81375; H01L 2224/81379; H10H 20/0364; H10H 20/857

(57) ABSTRACT

In a method of manufacturing a display device, the method includes forming a first electrode on a substrate, forming an insulating layer over the first electrode, aligning a first light emitting element on the insulating layer, light-exposing the insulating layer, exposing at least a portion of the first electrode by developing the insulating layer, and bonding the first light emitting element to the at least a portion of the first electrode.

### CROSS-REFERENCE TO RELATED APPLICATION(S)

This application claims priority to and benefits of Korean patent application No. 10-2023-0191537 under 35 U.S.C. § 119 (a), filed on Dec. 26, 2023 in the Korean Intellectual Property Office, the entire contents of which are incorporated herein by reference.

### BACKGROUND

### 1. Technical Field

The disclosure relates to a method of bonding a light emitting element and a method of manufacturing a display device, having the same.

### 2. Description of the Related Art

With the development of information technologies, the importance of a display device which is a connection medium between a user and information increases. Accordingly, display devices such as a liquid crystal display device, an organic light emitting display device, and an inorganic light emitting display device are increasingly used.

### SUMMARY

Embodiments provide a method of manufacturing a display device, in which a light emitting element is used as a mask.

Embodiments also provide a method of bonding a light emitting element, in which the light emitting element is used as a mask.

In accordance with an aspect of the disclosure, there is provided a method of manufacturing a display device. The method may include forming a first electrode on a substrate, forming an insulating layer over the first electrode, aligning a first light emitting element on the insulating layer, light-exposing the insulating layer, exposing at least a portion of the first electrode by developing the insulating layer, and bonding the first light emitting element to the at least a portion of the first electrode.

The first light emitting element may include a first bonding electrode bonded to the at least a portion of the first electrode.

The first light emitting element may further include a semiconductor layer, and a reflective electrode disposed between the semiconductor layer and the first bonding electrode.

The bonding of the first light emitting element may include locating the first bonding electrode in an opening of the insulating layer, which exposes the at least a portion of the first electrode, and melting the first bonding electrode.

An opening of the insulating layer, which exposes the at least a portion of the first electrode, may be formed at a position corresponding to a position of the first bonding electrode.

A second electrode spaced apart from the first electrode may be formed in the forming of the first electrode. At least a portion of the second electrode may be exposed in the developing of the insulating layer. The first light emitting element may be bonded to the at least a portion of the first electrode and the at least a portion of the second electrode.

The first light emitting element may include a second bonding electrode bonded to the at least a portion of the second electrode.

The insulating layer may include a photosensitive organic insulating material.

The first light emitting element may be bonded to the first electrode of a first sub-pixel. The method may further include bonding an additional light emitting element to the first electrode of a repair area adjacent to the first sub-pixel in case that the first light emitting element is defective.

The bonding of the additional light emitting element may include aligning the additional light emitting element in the repair area on the insulating layer, light-exposing the insulating layer, exposing at least a portion of the first electrode of the repair area by developing the insulating layer, and bonding the additional light emitting element to the at least a portion of the first electrode of the repair area.

The first light emitting element may be bonded to the first electrode of a first sub-pixel. The method may further include bonding an additional light emitting element to the first electrode of an overlapping area adjacent to the first sub-pixel.

The additional light emitting element may be driven in case that the first light emitting element becomes defective.

The first light emitting element may be bonded to the first electrode of a first sub-pixel. The method may further include aligning a second light emitting element in a second sub-pixel on the insulating layer, repeating the light-exposing of the insulating layer, exposing at least a portion of the first electrode of the second sub-pixel by re-developing the insulating layer, and bonding the second light emitting element to the at least a portion of the first electrode of the second sub-pixel.

The first sub-pixel and the second sub-pixel may display different colors.

In accordance with another aspect of the disclosure, there is provided a method of bonding a light emitting element. The method may include aligning a light emitting element on an insulating layer formed over an electrode, light-exposing the insulating layer, exposing at least a portion of the electrode by developing the insulating layer, and bonding the light emitting element to the at least a portion of the electrode.

The light emitting element may include a bonding electrode bonded to the at least a portion of the electrode.

The bonding of the light emitting element may include, locating the bonding electrode in an opening of the insulating layer, which exposes the at least a portion of the electrode, and melting the bonding electrode.

An opening of the insulating layer, which exposes the at least a portion of the electrode, may be formed at a position corresponding to a position of the bonding electrode.

The light emitting element may further include a semiconductor layer, and a reflective electrode disposed between the semiconductor layer and the bonding electrode.

The insulating layer may include a photosensitive organic insulating material.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic block diagram illustrating an embodiment of a display device.

FIG. 2 is a schematic block diagram illustrating an embodiment of any of sub-pixels shown in FIG. 1.

FIG. 3 is a schematic plan view illustrating an embodiment of a display panel shown in FIG. 1.

FIG. 4 is a schematic sectional view illustrating an embodiment of the display panel shown in FIG. 3.

FIG. 5 is a schematic sectional view illustrating another embodiment of the display panel shown in FIG. 3.

FIG. 6 is a schematic plan view illustrating an embodiment of any of pixels shown in FIG. 3.

FIG. 7 is a schematic sectional view taken along line I-I′ shown in FIG. 6.

FIG. 8 is a schematic sectional view taken along line II-II′ shown in FIG. 6.

FIG. 9 schematically illustrates a method of manufacturing the display device in accordance with embodiments of the disclosure.

FIGS. 10 to 17 are schematic views sequentially illustrating the method shown in FIG. 9.

FIGS. 18 and 19 are schematic views illustrating that a first light emitting element is aligned at a dislocated position.

FIG. 20 is a schematic view illustrating that a first light emitting element of a display device is bonded in accordance with embodiments of the disclosure.

FIG. 21 is a schematic plan view illustrating a pixel of a display device in accordance with embodiments of the disclosure.

FIG. 22 is a schematic sectional view taken along line X-X′ shown in FIG. 21.

FIG. 23 is a schematic view illustrating that light exposure is performed to bond the first light emitting element shown in FIG. 21.

FIGS. 24 and 25 are schematic plan views illustrating a first sub-pixel of a display device and a repair area in accordance with embodiments of the disclosure.

FIG. 26 is a schematic plan view illustrating a first sub-pixel of a display device and an overlapping area in accordance with embodiments of the disclosure.

FIG. 27 is a schematic plan view illustrating an example in which first to third light emitting elements are disposed in the pixel shown in FIG. 6.

FIG. 28 is a schematic block diagram illustrating an embodiment of a display system.

FIGS. 29 to 32 are schematic perspective views illustrating application examples of the display system shown in FIG. 28.

### DETAILED DESCRIPTION OF THE EMBODIMENTS

Hereinafter, embodiments of the disclosure will be described in more detail with reference to the accompanying drawings. In the description below, only portions to help in understanding an operation according to the disclosure are described and the descriptions of other parts may be omitted in order not to unnecessarily obscure subject matters of the disclosure. In addition, the disclosure is not limited to embodiments described herein, but may be embodied in various different forms. Rather, embodiments described herein are provided to thoroughly and completely describe the disclosed contents and to sufficiently transfer the ideas of the disclosure to a person of ordinary skill in the art.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiment. It will be understood that when a component “comprises,” “has,” or “includes” an element, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XY, YZ, XZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of ideal embodiments (and an intermediate structure) of the disclosure, so that changes in a shape as shown due to, for example, manufacturing technology and/or a tolerance may be expected. Therefore, the embodiments of the disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

It will be understood that the terms “connected to” or “coupled to” may include a physical or electrical connection or coupling.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

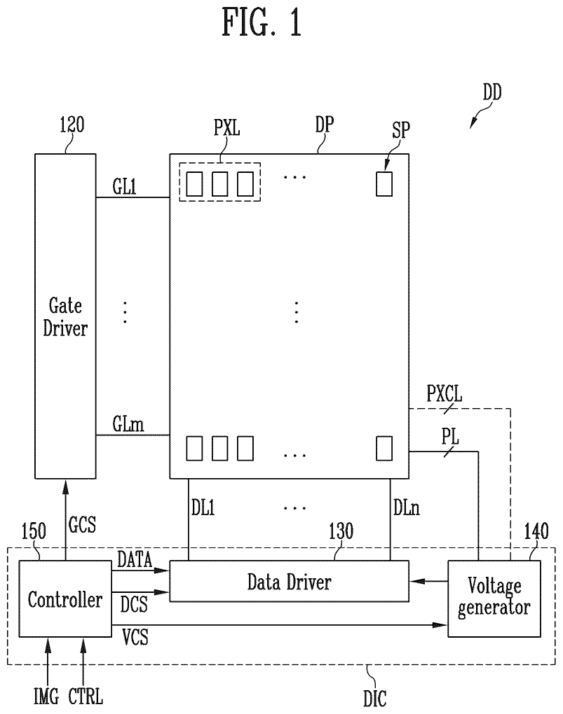

FIG. 1 is a schematic block diagram illustrating an embodiment of a display device.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to mth gate lines GL1 to GLm. The sub-pixels SP may be connected to the data driver 130 through first to nth data lines DL1 to DLn.

The sub-pixels SP may generate lights of two or more colors. For example, each of the sub-pixels SP may generate lights of red, green, blue, cyan, magenta, yellow, white, and the like.

Two or more sub-pixels SP among the sub-pixels SP may constitute a pixel PXL. For example, the pixel PXL may include three sub-pixels SP as shown in FIG. 1. As such, the pixel PXL may emit lights of various colors with various luminances according to a combination of lights emitted from the sub-pixels SP included therein.

The gate driver 120 may be connected to the sub-pixels SP arranged in a row direction through the first to mth gate lines GL1 to GLm. The gate driver 120 may output gate signals to the first to mth gate lines GL1 to GLm in response to a gate control signal GCS. In embodiments, the gate control signal GCS may include a start signal indicating a start of each frame, a horizontal synchronization signal, and the like.

The gate driver 120 may be disposed at a side of the display panel DP. However, embodiments are not limited thereto. For example, the gate driver 120 may be divided into two or more drivers which are physically and/or logically divided, and these drivers may be disposed at a side of the display panel DP and another side of the display panel DP, which may be opposite to the first side. As such, in some embodiments, the gate driver 120 may be disposed in various forms at the periphery of the display panel DP.

The data driver 130 may be connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. In embodiments, the data control signal DCS may include a source start pulse signal, a source shift clock signal, a source output enable signal, and the like.

The data driver 130 may receive voltages from the voltage generator 140. The data driver 130 may apply data signals having grayscale voltages corresponding to the image data DATA to the first to nth data lines DL1 to DLn by using the received voltages. In case that a gate signal is applied to each of the first to mth gate lines GL1 to GLm, data signals corresponding to the image data DATA may be applied to the first to nth data line DL1 to DLm. Accordingly, corresponding sub-pixels SP may generate light corresponding to the data signals. Accordingly, an image may be displayed on the display panel DP.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate voltages and provide the generated voltages to components of the display device DD. The voltage generator 140 may generate voltages by receiving an input voltage from the outside of the display device DD and regulating the received voltage.

The voltage generator 140 may generate a first power voltage and a second power voltage. The generated first and second power voltages may be provided to the sub-pixels SP through power lines PL. In other embodiments, at least one of the first and second power voltages may be provided from the outside of the display device DD.

The voltage generator 140 may provide various voltages and/or signals. For example, the voltage generator 140 may provide one or more initialization voltages applied to the sub-pixels SP. For example, in a sensing operation for sensing electrical characteristics of transistors and/or light emitting elements of the sub-pixels SP, a predetermined or selected reference voltage may be applied to the first to nth data lines DL1 to DLn, and the voltage generator 140 may generate the reference voltage and transfer the reference voltage to the data driver 130. For example, in a display operation for displaying an image on the display panel DP, common pixel control signals may be applied to the sub-pixels SP, and the voltage generator 140 may generate the pixel control signals. In embodiments, the voltage generator 140 may provide the pixel control signals to the sub-pixels SP through pixel control lines PXCL. In FIG. 1, it is illustrated that the pixel control lines PXCL are connected between the voltage generator 140 and the display panel DP. However, embodiments are not limited thereto. For example, the pixel control lines PXCL may be connected between the gate driver 120 and the display panel DP. The pixel control signals may be transferred to the sub-pixels SP from the gate driver 120 through the pixel control lines PXCL.

The controller 150 may control overall operations of the display device DD. The controller 150 may receive, from the outside, input image data IMG and a control signal CTRL corresponding thereto. The controller 150 may provide the gate control signal GCS, the data control signal DCS, and the voltage control signal VCS in response to the control signal CTRL.

The controller 150 may convert the input image data IMG to be suitable for the display device DD or the display panel DP, thereby outputting the image data DATA. In embodiments, the controller 150 may align the input image data IMG to be suitable for the sub-pixels SP in units of rows, thereby outputting the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. In other embodiments, at least one of the data driver 130, the voltage generator 140, and the controller 150 may be provided as a component distinguished from the driver integrated circuit DIC.

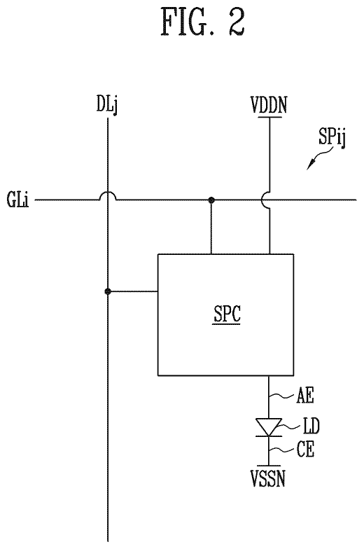

FIG. 2 is a schematic block diagram illustrating an embodiment of any of the sub-pixels shown in FIG. 1. In FIG. 2, a sub-pixel SPij arranged on an ith row (i is an integer which is greater than or equal to 1 and is smaller than or equal to m) and a jth column (j is an integer which is greater than or equal to 1 and is smaller than or equal to n) among the sub-pixels SP shown in FIG. 1 is illustrated.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be connected to one of the power lines PL shown in FIG. 1, to receive a first power voltage. The second power voltage node VSSN may be connected to another of the power lines PL, to receive a second power voltage. The first power voltage may have a voltage level higher than a voltage level of the second power voltage.

The light emitting element LD may be connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD may be configured to emit light according to a current flowing from the anode electrode AE to the cathode electrode CE.

The sub-pixel circuit SPC may be connected to an ith gate line GLi among the first to mth gate lines GL1 to GLm shown in FIG. 1 and a jth data line DLj among the first to nth data lines DL1 to DLn shown in FIG. 1. In response to a gate signal received through the ith gate line GLi, the sub-pixel circuit SPC may control the light emitting element LD to emit light according to a data signal received through the jth data line DLj. In embodiments, the sub-pixel circuit SPC may be further connected to the pixel control lines PXCL shown in FIG. 1. The sub-pixel circuit SPC may control the light emitting element LD in further response to control signals received through the pixel control lines PXCL.

For these operations, the sub-pixel circuit SPC may include circuit elements, e.g., transistors and one or more capacitors.

The transistors of the sub-pixel circuit SPC may include P-type transistors and/or N-type transistors. In embodiments, the transistors of the sub-pixel circuit SPC may include a Metal Oxide Semiconductor Field Effect Transistor (MOSFET). In embodiments, the transistors of the sub-pixel circuit SPC may include an amorphous silicon semiconductor, a monocrystalline silicon semiconductor, polycrystalline silicon semiconductor, an oxide semiconductor, and the like.

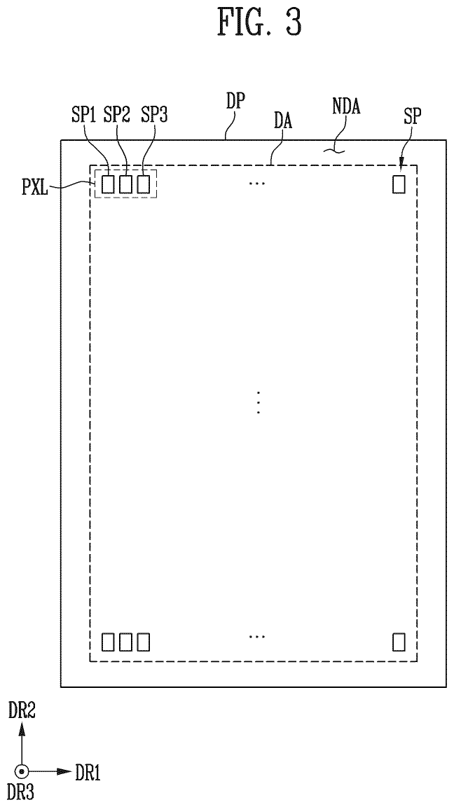

FIG. 3 is a schematic plan view illustrating an embodiment of the display panel shown in FIG. 1.

Referring to FIG. 3, a display panel DP may include a display area DA and a non-display area NDA. The display panel DP may display an image through the display area DA. The non-display area NDA may be disposed at the periphery of the display area DA.

The display panel DP may include sub-pixels SP in the display area DA. The sub-pixels SP may be arranged in a first direction DR1 and a second direction DR2 intersecting the first direction DR1. For example, the sub-pixels SP may be arranged in a matrix form along the first direction DR1 and the second direction DR2. In another example, the sub-pixels SP may be arranged in a zigzag form along the first direction DR1 and the second direction DR2. The arrangement of the sub-pixels SP may vary in some embodiments. The first direction DR1 may be a row direction, and the second direction DR2 may be a column direction.

Two or more sub-pixels SP among the sub-pixels SP may constitute one pixel PXL. In FIG. 3, it is illustrated that the pixel PXL includes three sub-pixels SP1 to SP3. However, embodiments are not limited thereto. For example, the pixel PXL may include two sub-pixels SP. Hereinafter, for convenience of description, it is assumed that the pixel PXL includes first to third sub-pixels SP1 to SP3.

Each of the first to third sub-pixels SP1 to SP3 may generate light of one of various colors such as red, green, blue, cyan, magenta, and yellow. Hereinafter, for clear and simple description, it is assumed that the first sub-pixel SP1 is configured to generate light of a red color, the second sub-pixel SP2 is configured to generate light of a green color, and the third sub-pixel SP3 is configured to generate light of a blue color.

Each of the first to third sub-pixels SP1 to SP3 may include at least one light emitting element configured to generate light. In embodiments, light emitting elements of the first to third sub-pixels SP1 to SP3 may generate light of the same color. For example, the light emitting elements of the first to third sub-pixels SP1 to SP3 may generate light of a blue color. In other embodiments, the light emitting elements of the first to third sub-pixels SP1 to SP3 may generate lights of different colors. For example, the light emitting elements of the first to third sub-pixels SP1 to SP3 may generate lights of a red color, a green color, and a blue color, respectively.

Self-luminous display panels, such as a light emitting diode display panel (LED display panel) using a light emitting diode of micro scale or nano scale as a light emitting element and an organic light emitting display panel (OLED panel) using an organic light emitting diode as a light emitting element, may be used as the display panel DP.

A component for controlling the sub-pixels SP may be disposed in the non-display area NDA. Lines connected to the sub-pixels SP, e.g., the first to mth gate lines GL1 to GLm, the first to nth data lines DL1 to DLn, the power lines PL, and the pixel control lines PXCL, which are shown in FIG. 1, may be disposed in the non-display area NDA.

At least one of the gate driver 120, the data driver 130, the voltage generator 140, and the controller 150, which are shown in FIG. 1, may be disposed in the non-display area NDA of the display panel DP. In embodiments, the gate driver 120 may be disposed in the non-display area NDA. The data driver 130, the voltage generator 140, and the controller 150 may be implemented into the driver integrated circuit DIC shown in FIG. 1, which is distinguished from the display panel DP, and the driver integrated circuit DIC may be connected to the lines disposed in the non-display area NDA. In other embodiments, the gate driver 120, the data driver 130, the voltage generator 140, and the controller 150 may be implemented into one integrated circuit distinguished from the display panel DP.

In embodiments, the display area DA may have various shapes. The display area DA may have a closed-loop shape including linear sides and/or curved sides. For example, the display area DA may have shapes such as a polygon, a circle, a semicircle, and an ellipse.

In embodiments, the display panel DP may have a flat display surface. In other embodiments, the display panel DP may at least partially have a round display surface. In embodiments, the display panel DP may be bendable, foldable or rollable. The display panel DP and/or a substrate of the display panel DP may include materials having flexibility.

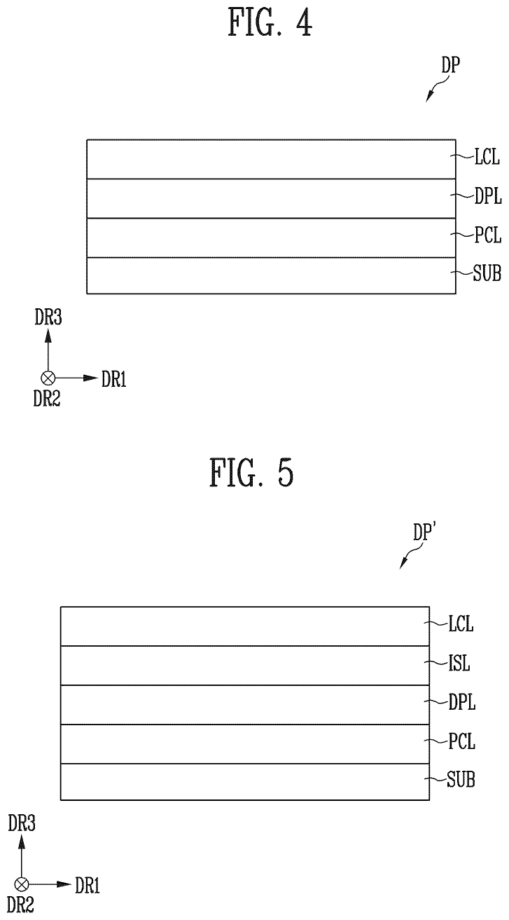

FIG. 4 is a schematic sectional view illustrating an embodiment of the display panel shown in FIG. 3.

Referring to FIG. 4, a display panel DP may include a substrate SUB, and a pixel circuit layer PCL, a display panel layer DPL, and a light conversion layer LCL, which are sequentially stacked on each other in a third direction DR3 intersecting the first and second directions DR1 and DR2 on the substrate SUB.

The substrate SUB may be made of an insulative material such as glass or resin. For example, the substrate SUB may include a glass substrate. In another example, the substrate SUB may include polyimide (PI) substrate. In still another example, the substrate SUB may include a silicon wafer substrate formed using a semiconductor process.

In embodiments, the substrate SUB may be made of a material having flexibility to be curvable or foldable, and have a single-layer structure or a multi-layer structure. For example, the material having flexibility may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers, and semiconductor patterns and conductive patterns, which are disposed between the insulating layers. The conductive patterns of the pixel circuit layer PCL may serve as circuit elements, lines, and the like.

The circuit elements of the pixel circuit layer PCL may include the sub-pixel circuit SPC (see FIG. 2) of each of the sub-pixels SP shown in FIG. 3. In other words, the circuit elements of the pixel circuit layer PCL may be provided as transistors and one or more capacitors of the sub-pixel circuit SPC.

The lines of the pixel circuit layer PCL may include lines connected to each of the sub-pixels SP. The lines of the pixel circuit layer PCL may include various signal lines and/or various voltage lines, which are for driving the display panel layer DPL.

The display panel layer DPL may be disposed on the pixel circuit layer PCL. The display panel layer DPL may include light emitting elements of the sub-pixels SP.

The light conversion layer LCL may be disposed on the display panel layer DPL. The light conversion layer LCL may include light conversion patterns having color conversion particles and/or light scattering particles. For example, color conversion particles may include quantum dots. The quantum dots may change a wavelength (or color) of light emitted from the display panel layer DPL. In embodiments, the light conversion patterns may be omitted.

The light conversion layer LCL may further include a color filter layer including color filters. The color filter may allow light having a specific wavelength (or specific color) to be selectively transmitted therethrough. In embodiments, the color filter layer may be omitted.

A window for protecting an exposed surface (or top surface) of the display panel DP may be provided on the light conversion layer LCL. The window may protect the display panel DP from external impact. The window may be bonded to the light conversion layer LCL through an optically transparent adhesive (or cohesive) member. The window may have a multi-layer structure selected from a glass substrate, a plastic film, and a plastic substrate. This multi-layer structure may be formed through a continuous process or an adhesive process using an adhesive layer. The whole or a portion of the window may have flexibility.

FIG. 5 is a schematic sectional view illustrating another embodiment of the display panel shown in FIG. 3.

Referring to FIG. 5, a display panel DP′ may include a substrate SUB, a pixel circuit layer PCL, a display panel layer DPL, an input sensing layer ISL, and a light conversion layer LCL. The substrate SUB, the pixel circuit layer PCL, the display panel layer DPL, and the light conversion layer LCL may be configured identically to the substrate SUB, the pixel circuit layer PCL, the display panel layer DPL, and the light conversion layer LCL, which are described with reference to FIG. 4, respectively. Hereinafter, redundant descriptions will be omitted.

The input sensing layer ISL may sense a user input with respect to a top surface (or display surface) of the display panel DP′. The input sensing layer ISL may include components suitable for sensing an external object such as a hand of a user or a pen. For example, the input sensing layer ISL may include touch electrodes.

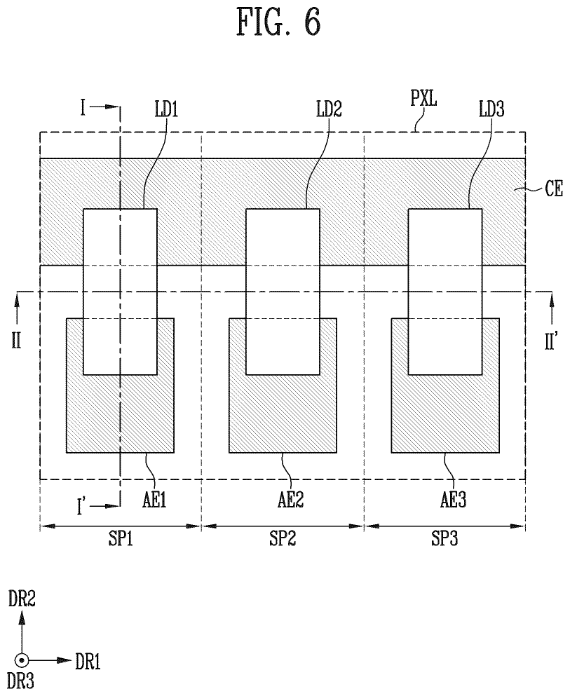

FIG. 6 is a schematic plan view illustrating an embodiment of any of the pixels shown in FIG. 3.

Referring to FIG. 6, a pixel PXL may include first to third sub-pixels SP1 to SP3. The first to third sub-pixels SP1 to SP3 may be arranged in the first direction DR1. However, the arrangement of the pixel PXL is not limited thereto, and may be variously changed in some embodiments. For example, the first to third sub-pixels SP1 to SP3 may be arranged in a zigzag form.

First to third anode electrodes AE1 to AE3 may be disposed in the first to third sub-pixels SP1 to SP3, respectively. The first anode electrode AE1 may be provided as an anode electrode AE (see FIG. 2) connected to a sub-pixel circuit SPC (see FIG. 2) of the first sub-pixel SP1. The second anode electrode AE2 may be provided as an anode electrode AE connected to a sub-pixel circuit SPC of the second sub-pixel SP2. The third anode electrode AE3 may be provided as an anode electrode AE connected to a sub-pixel circuit SPC of the third sub-pixel SP3.

A cathode electrode CE may be spaced apart from the first to third anode electrodes AE1 to AE3. The cathode electrode CE may be disposed at the same height as the first to third anode electrodes AE1 to AE3. The cathode electrode CE may be spaced apart from the first to third anode electrodes AE1 to AE3 in the second direction DR2. In embodiments, the cathode electrode CE may extend in the first direction DR1, to be used as a common electrode for the pixel PXL and other pixels adjacent to the pixel PXL. Although not shown in the drawing, the cathode electrode CE may extend in the second direction DR2 in addition to the first direction DR1, to be used as a common electrode for all the sub-pixels SP shown in FIG. 3. As such, the cathode electrode CE may have various shapes.

First to third light emitting elements LD1 to LD3 may be disposed on the first to third anode electrodes AE1 to AE3 and the cathode electrode CE. The first light emitting element LD1 may be electrically connected to the first anode electrode AE1 and the cathode electrode CE. The first light emitting element LD1 may be provided as a light emitting element LD (see FIG. 2) connected to the sub-pixel circuit SPC of the first sub-pixel SP1. The second light emitting element LD2 may be electrically connected to the second anode electrode AE2 and the cathode electrode CE. The second light emitting element LD2 may be provided as a light emitting element LD connected to the sub-pixel circuit SPC of the second sub-pixel SP2. The third light emitting element LD3 may be electrically connected to the third anode electrode AE3 and the cathode electrode CE. The third light emitting element LD3 may be provided as a light emitting element LD connected to the sub-pixel circuit SPC of the third sub-pixel SP3.

The first light emitting element LD1, the second light emitting element LD2, and the third light emitting element LD3 may be inorganic light emitting diodes including an inorganic light emitting material. However, embodiments are not limited thereto. For example, organic light emitting diodes may be used.

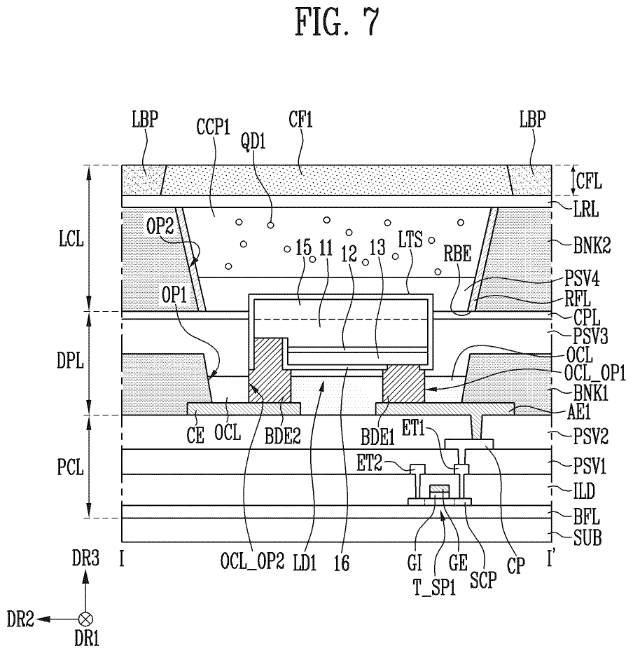

FIG. 7 is a schematic sectional view taken along line I-I′ shown in FIG. 6.

Referring to FIGS. 6 and 7, a pixel circuit layer PCL, a display panel layer DPL, and a light conversion layer LCL may be sequentially disposed on a substrate SUB.

The pixel circuit layer PCL may include insulating layers, semiconductor patterns, and conductive patterns, which are stacked on each other on the substrate SUB. The insulating layers may include a buffer layer BFL, one or more interlayer insulating layers ILD, and one or more passivation layers PSV1 and PSV2. The semiconductor patterns and the conductive patterns may be located between the insulating layers. The conductive patterns may include at least one material among copper (Cu), molybdenum (Mo), tungsten (W), aluminum neodymium (AlNd), titanium (Ti), aluminum (Al), and silver (Ag).

As described with reference to FIG. 2, the sub-pixel circuit SPC (see FIG. 2) of each of the first to third sub-pixels SP1 to SP3 may include transistors and one or more capacitors. The semiconductor patterns and the conductive patterns of the pixel circuit layer PCL may serve as the transistors and the capacitors of the sub-pixel circuit SPC. The conductive patterns of the pixel circuit layer PCL may further serve as lines, e.g., the first to mth gate lines GL1 to GLm, the first to nth data lines DL1 to DLn, the power lines PL, and the pixel control lines PXCL, which are shown in FIG. 1.

The buffer layer BFL may be disposed on a surface of the substrate SUB. The buffer layer BFL may prevent an impurity from being diffused into circuit elements and lines, which are included in the pixel circuit layer PCL. The buffer layer BFL may include an inorganic insulating layer including an inorganic material. In embodiments, the buffer layer BFL may include at least one of silicon nitride (SiNₓ), silicon oxide (SiOₓ), silicon oxynitride (SiOₓN_{y}), and a metal oxide such as aluminum oxide (AlOₓ). The buffer layer BFL may be provided as a single layer or a multi-layer. In case that the buffer layer BFL is provided as the multi-layer, layers of the multi-layer may be formed of the same material or be formed of different materials.

In embodiments, one or more barrier layers may be disposed between the substrate SUB and the buffer layer BFL. Each of the barrier layers may include polyimide.

A transistor T_SP1 may be disposed on the buffer layer BFL. The transistor T_SP1 may be any of the transistors of the sub-pixel circuit SPC included in the first sub-pixel SP1. For example, the transistor T_SP1 may be understood as a transistor connected to a first anode electrode AE1 among the transistors of the sub-pixel circuit SPC.

The transistor T_SP1 may include a semiconductor pattern SCP, a gate electrode GE, a first terminal ET1, and a second terminal ET2. The first terminal ET1 may be any of a source electrode and a drain electrode, and the second terminal ET2 may be the other of the source electrode and the drain electrode. For example, the first terminal ET1 may be the source electrode, and the second terminal ET2 may be the drain electrode.

The semiconductor pattern SCP may be disposed on the buffer layer BFL. The semiconductor pattern SCP may include a first contact region in contact with the first terminal ET1 and a second contact region in contact with the second terminal ET2. A region between the first contact region and the second contact region may be a channel region. The channel region may overlap the gate electrode GE of the transistor T_SP1. The channel region may be a semiconductor pattern undoped with an impurity, and may be an intrinsic semiconductor. Each of the first contact region and the second contact region may be a semiconductor pattern doped with the impurity. For example, a p-type impurity may be used as the impurity, but embodiments are not limited thereto.

The semiconductor pattern SCP may include any of various types of semiconductors, e.g., any of an amorphous silicon semiconductor, a monocrystalline silicon semiconductor, a polycrystalline silicon semiconductor, a low temperature poly-silicon semiconductor, and an oxide semiconductor.

The sequentially stacked interlayer insulating layers ILD may be disposed over the semiconductor pattern SCP. The interlayer insulating layers ILD may be inorganic insulating layers including an inorganic material. For example, each of the interlayer insulating layers ILD may include at least one of silicon nitride (SiNₓ), silicon oxide (SiOₓ), silicon oxynitride (SiOₓN_{y}), and a metal oxide such as aluminum oxide (AlOₓ). However, the interlayer insulating layers ILD are not limited thereto. For example, any of the interlayer insulating layers ILD may include an organic insulating layer including an organic material.

The interlayer insulating layers ILD may electrically separate the conductive patterns and/or the semiconductor patterns, which are disposed between the interlayer insulating layers ILD. For example, the interlayer insulating layers ILD may include a gate insulating layer GI disposed on the semiconductor pattern SCP. The gate insulating layer GI may be disposed between the semiconductor pattern SCP and the gate electrode GE such that the gate electrode GE is spaced apart from the semiconductor pattern SCP. In embodiments, the gate insulating layer GI may be entirely provided on the semiconductor pattern SCP and the buffer layer BFL, to cover the semiconductor pattern SCP and the buffer layer BFL. As the number of layers required in the conductive patterns and/or the semiconductor patterns increases, the number of interlayer insulating layers ILD may increase.

The gate electrode GE may be disposed on the gate insulating layer GI. The gate electrode GE may overlap the channel region of the semiconductor pattern SCP. The gate electrode GE may be provided as a single layer including at least one material among copper (Cu), molybdenum (Mo), tungsten (W), aluminum neodymium (AlNd), titanium (Ti), aluminum (Al), and silver (Ag). In embodiments, the gate electrode GE may be provided as a multi-layer including at least one material among molybdenum (Mo), titanium (Ti), copper (Cu), aluminum (Al), and silver (Ag), which are low resistance materials.

The first and second terminals ET1 and ET2 may be disposed on the interlayer insulating layers ILD. The first and second terminals ET1 and ET2 may be in contact with the semiconductor pattern SCP through contact holes penetrating the interlayer insulating layers ILD. The first and second terminals ET1 and ET2 may be in contact with the first and second contact regions of the semiconductor pattern SCP, respectively. Each of the first and second terminals ET1 and ET2 may include at least one material among copper (Cu), molybdenum (Mo), tungsten (W), aluminum neodymium (AlNd), titanium (Ti), aluminum (Al), and silver (Ag).

Although the first and second terminals ET1 and ET2 are illustrated as separate electrodes electrically connected to the semiconductor pattern SCP, embodiments are not limited thereto. In some embodiments, the first terminal ET1 may be the first contact region adjacent to a side of the channel region of the semiconductor pattern SCP, and the second terminal ET2 may be the second contact region adjacent to another side of the channel region of the semiconductor pattern SCP. The first terminal ET1 may be electrically connected to the first light emitting element LD1 through a connection means such as a bridge electrode disposed on at least one of the interlayer insulating layers ILD.

In embodiments, the transistor T_SP1 may be configured as a low temperature poly-silicon transistor. However, embodiments are not limited thereto. For example, the transistor T_SP1 may be configured as an oxide semiconductor transistor. In embodiments, the sub-pixel circuit of the first sub-pixel SP1 may include different types of transistors. For example, the transistor T_SP1 may be configured as a low temperature poly-silicon transistor, and another transistor of the first sub-pixel SP1 may be configured as an oxide semiconductor transistor. An oxide semiconductor of the corresponding oxide semiconductor transistor may be disposed on any of the interlayer insulating layers ILD instead of an insulating layer on which the semiconductor pattern SCP of the transistor T_SP1 is disposed.

In embodiments, a case where the transistor T_SP1 is a transistor having a top gate structure is described as an example. However, embodiments are not limited thereto. For example, the transistor T_SP1 may be a transistor having a bottom gate structure. The structure of the transistor T_SP1 may be variously changed.

At least a portion of various lines of the display panel DP and/or the display device DD may be further disposed on the interlayer insulating layers ILD.

A first passivation layer PSV1 may be disposed over first to third transistors T_SP1 to T_SP3. The passivation layer may be designated as a protective layer or a via layer. The first passivation layer PSV1 may protect components disposed thereunder, and provide a flat top surface.

A connection pattern CP may be disposed on the first passivation layer PSV1. The connection pattern CP may be connected to the first terminal ET1 of the transistor T_SP1 while penetrating the first passivation layer PSV1. The connection pattern CP may include at least one material among copper (Cu), molybdenum (Mo), tungsten (W), aluminum neodymium (AlNd), titanium (Ti), aluminum (Al), and silver (Ag).

At least a portion of various lines of the display panel DP and/or the display device DD may be further disposed on the first passivation layer PSV1.

A second passivation layer PSV2 may be disposed on the connection pattern CP and the first passivation layer PSV1. The second passivation layer PSV2 may protect components disposed thereunder, and provide a flat top surface.

Each of the first and second passivation layers PSV1 and PSV2 may include an inorganic insulating layer including an inorganic material and/or an organic insulating layer including an organic material. The inorganic insulating layer may include, for example, at least one of silicon oxide (SiOₓ), silicon nitride (SiNₓ), silicon oxynitride (SiOₓN_{y}), and a metal oxide such as aluminum oxide (AlOₓ). The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin.

The first and second passivation layers PSV1 and PSV2 may include the same material as any of the interlayer insulating layers ILD, but embodiments are not limited thereto. Each of the first and second passivation layers PSV1 and PSV2 may be provided as a single layer, but may also be provided as a multi-layer.

The display panel layer DPL may be disposed on the second passivation layer PSV2. The display panel layer DPL may include the first anode electrode AE1, a cathode electrode CE, a first bank BNK1, the first light emitting element LD1, an insulating layer OCL, a third passivation layer PSV3, and a capping layer CPL.

The first anode electrode AE1 and the cathode electrode CE may be disposed on the pixel circuit layer PCL.

The first anode electrode AE1 may be electrically connected to the connection pattern CP through a contact hole penetrating the second passivation layer PSV2. As such, the first anode electrode AE1 may be electrically connected to the first transistor T_SP1.

The cathode electrode CE may be spaced apart from the first anode electrode AE1 in the second direction DR2. The cathode electrode CE may be electrically connected to the second power voltage node VSSN shown in FIG. 2. Accordingly, the second power voltage applied to the second power voltage node VSSN may be transferred to the cathode electrode CE.

The first bank BNK1 may be disposed on the first anode electrode AE1 and the cathode electrode CE. The first bank BNK1 may have a first opening OP1 exposing portions of the first anode electrode AE1 and the cathode electrode CE. The first light emitting element LD1 may be disposed in the first opening OP1 of the first bank BNK1. As such, the first bank BNK1 may be provided as a pixel defining layer defining an area in which the first light emitting element LD1 is located.

The first bank BNK1 may be configured to include a light blocking material, to prevent light mixture between adjacent sub-pixels. In embodiments, the first bank BNK1 may include an organic material. For example, the first bank BNK1 may include an organic insulating material such as acrylic resin, epoxy resin, phenolic resin, polyamide resin, or polyimide resin.

The first light emitting element LD1 may be electrically connected to the first anode electrode AE1. The first light emitting element LD1 may be electrically connected to the cathode electrode CE. The first light emitting element LD1 may be bonded to the first anode electrode AE1 and the cathode electrode CE.

The first light emitting element LD1 may include a first semiconductor layer 11, an active layer 12, a second semiconductor layer 13, and an auxiliary layer 15. The first light emitting element LD1 may include a light emitting stack structure in which the auxiliary layer 15, the first semiconductor layer 11, the active layer 12, and the second semiconductor layer 13 are sequentially stacked on each other.

The first light emitting element LD1 may include first and second bonding electrodes BDE1 and BDE2 facing in the same direction (e.g., the opposite direction of the third direction DR3). The first bonding electrode BDE1 may be connected to the second semiconductor layer 13. The second bonding electrode BDE2 may be connected to the first semiconductor layer 11 exposed as the second semiconductor layer 13 and the active layer 12 are exposed. The first light emitting element LD1 may be a flip chip type light emitting element.

The first semiconductor layer 11 may be configured to provide electrons to the active layer 12. The first semiconductor layer 11 may include, for example, at least one n-type semiconductor layer. For example, the first semiconductor layer 11 may include at least one semiconductor material among gallium nitride (GaN), aluminum gallium nitride (AlGaN), indium gallium nitride (InGaN), aluminum nitride (AlN), and indium nitride (InN), and be an n-type semiconductor layer doped with a first conductive dopant (or n-type dopant) such as silicon (Si), germanium (Ge) or tin (Sn). However, the material constituting the first semiconductor layer 11 is not limited thereto. Various materials may constitute the first semiconductor layer 11. In an embodiment of the disclosure, the first semiconductor layer 11 may include a gallium nitride (GaN) semiconductor material doped with the first conductive dopant (or n-type dopant). In some embodiments, the first semiconductor layer 11 along with the auxiliary layer 15 may constitute an n-type semiconductor layer.

The active layer 12 may be disposed on the first semiconductor layer 11, and may be an area in which electrons and holes are recombined. As electrons and holes are recombined in the active layer 12, light may be generated, which has a level changed to a low energy level and has a wavelength corresponding to the low energy level. The active layer 12 may be formed in a single quantum well structure or a multi-quantum well structure. In case that the active layer 12 is formed in the multi-quantum well structure, a unit including a barrier layer, a strain reinforcing layer, and a well layer may be repeatedly stacked on each other, to form the active layer 12. However, embodiments of the active layer 12 are not limited thereto.

The second semiconductor layer 13 may be disposed on the active layer 12, and may provide holes to the active layer 12. The second semiconductor layer 13 may include a semiconductor layer of which type is different from the type of the first semiconductor layer 11. In an example, the second semiconductor layer 13 may include at least one p-type semiconductor layer. For example, the second semiconductor layer 13 may include at least one semiconductor material among gallium nitride (GaN), aluminum gallium nitride (AlGaN), indium gallium nitride (InGaN), aluminum nitride (AlN), and indium nitride (InN), and be a p-type semiconductor layer doped with a second conductive dopant (or p-type dopant) such as magnesium (Mg), zinc (Zn), calcium (Ca), strontium (Sr) or barium (Ba). However, the material constituting the second semiconductor layer 13 is not limited thereto. Various materials may constitute the second semiconductor layer 13. In an embodiment of the disclosure, the second semiconductor layer 13 may include a gallium nitride (GaN) semiconductor material doped with the second conductive dopant (or p-type dopant).

The auxiliary layer 15 may include a gallium nitride (GaN) semiconductor material undoped with an impurity. The auxiliary layer 15 along with the first semiconductor layer 11 may constitute an n-type semiconductor layer.

The first bonding electrode BDE1 may be electrically connected to the second semiconductor layer 13. The second bonding electrode BDE2 may be electrically connected to the first semiconductor layer 11. The first and second bonding electrodes BDE1 and BDE2 may include a eutectic metal.

The first light emitting element LD1 may further include an insulative film 16 covering an outer circumferential surface of the light emitting stack structure. The insulative film 16 may prevent an electrical short circuit which may occur while the active layer 12 is in contact with another conductive material except the first and second semiconductor layers 11 and 13. The insulative film 16 may include a transparent insulating material. The insulative film 16 may be configured to expose bottom surfaces of the first and second bonding electrodes BDE1 and BDE2.

The bottom surface of the first bonding electrode BDE1 may be in contact with the first anode electrode AE1. Accordingly, the first bonding electrode BDE1 may be electrically connected to the first anode electrode AE1. The bottom surface of the second bonding electrode BDE2 may be in contact with the cathode electrode CE. Accordingly, the second bonding electrode BDE2 may be electrically connected to the cathode electrode CE.

The insulating layer OCL may be disposed in the first opening OP1 in which the first light emitting element LD1 is disposed. The insulating layer OCL may fix the first light emitting element LD1 not to move. Also, the insulating layer OCL may protect components disposed thereunder from a foreign matter such as dust or moisture. Also, the insulating layer OCL may prevent a short circuit between the cathode electrode CE and the first anode electrode AE1. For example, the insulating layer OCL may include at least one of an inorganic insulating layer and an organic insulating layer.

In an embodiment, the insulating layer OCL may include a photosensitive organic insulating material. For example, the insulating layer OCL may include at least one of photosensitive polyimide (PSPI) and photo acryl. However, embodiments are not limited thereto.

The third passivation layer PSV3 may be disposed over the first bank BNK1 and the insulating layer OCL. The third passivation layer PSV3 may protect components disposed thereunder, and provide a flat surface. The third passivation layer PSV3 may include the same material as any of the first and second passivation layers PSV1 and PSV2, but embodiments are not limited thereto.

In embodiments, the third passivation layer PSV3 may not be disposed on a top surface LTS of the first light emitting element LD1. The first light emitting element LD1 may protrude to the light conversion layer LCL. The first light emitting element LD1 may be at least partially located in a second opening OP2 of a second bank BNK2. For example, a height of the top surface LTS of the first light emitting element LD1 from the substrate SUB may be higher than a height of a lowermost end RBE of a reflective layer RFL from the substrate SUB. Accordingly, light emitted from the first light emitting element LD1 may be provided to the light conversion layer LCL at a relatively high ratio.

The capping layer CPL may be disposed on the third passivation layer PSV3. The capping layer CPL may protect components disposed thereunder, such as the first light emitting element LD1, from external moisture, humidity, and the like. In embodiments, the capping layer CPL may not be disposed on the top surface LTS of the first light emitting element LD1. In other embodiments, the capping layer CPL may entirely cover the first light emitting element LD1 and the third passivation layer PSV3. The capping layer CPL may include at least one of silicon nitride (SiNₓ), silicon oxide (SiOₓ), silicon oxynitride (SiOₓN_{y}), and a metal oxide such as aluminum oxide (AlOₓ). However, the material of the capping layer CPL is not limited thereto.

In the above, the pixel circuit layer PCL and the display panel layer DPL of the first sub-pixel SP1 have been described. Each of the second and third sub-pixels SP2 and SP3 shown in FIG. 6 may also be configured identically to the first sub-pixel SP1 within a range in which it is not differently described herein.

The light conversion layer LCL may be disposed on the capping layer CPL. The light conversion layer LCL may include the second bank BNK2, the reflective layer RFL, a fourth passivation layer PSV4, a first light conversion pattern CCP1, a low refractive layer LRL, and a color filter layer CFL.

The second bank BNK2 may be disposed on the capping layer CPL. The second bank BNK2 may overlap the first bank BNK1. The second bank BNK2 may have the second opening OP2 overlapping the first opening OP1.

The second bank BNK2 may be configured to include a light blocking material, to prevent light mixture between adjacent sub-pixels. In embodiments, the second bank BNK2 may include an organic material. For example, the second bank BNK2 may include an organic insulating material such as acrylic resin, epoxy resin, phenolic resin, polyamide resin, or polyimide resin.

The reflective layer RFL may be disposed on side surfaces of the second bank BNK2, which are adjacent to the second opening OP2. The reflective layer RFL may be configured to reflect incident light, and accordingly, light emission efficiency can be improved. The reflective layer RFL may include a material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

On the capping layer CPL, the fourth passivation layer PSV4 may be disposed in the second opening OP2. The fourth passivation layer PSV4 may protect components disposed thereunder, and provide a flat surface. The fourth passivation layer PSV4 may include the same material as any of the first to third passivation layers PSV1 to PSV3, but embodiments are not limited thereto.

On the fourth passivation layer PSV4, the first light conversion pattern CCP1 may be disposed in the second opening OP2.

The first light conversion pattern CCP1 may include color conversion particles and/or light scattering particles. The color conversion particles may convert incident light into light of another color by changing a wavelength of the incident light. Also, the color conversion particles may scatter incident light. In embodiments, the color conversion particles may be quantum dots. The light scattering particles may scatter incident light.

The first sub-pixel SP1 may be a red sub-pixel. In case that the first light emitting element LD1 emits light of a blue color, the first light conversion pattern CCP1 may include first color conversion particles QD1 configured to convert light of the blue color into light of a red color. In case that the first light emitting element LD1 emits light of the red color, the first light conversion pattern CCP1 may include light scattering particles. As such, the particles included in the first light conversion pattern CCP1 may be variously changed according to the first light emitting element LD1.

The low refractive layer LRL may be disposed on the second bank BNK2, the reflective layer RFL, and the first light conversion pattern CCP1. The low refractive layer LRL may have a refractive index lower than a refractive index of each of the first light conversion pattern CCP1 and a first color filter CF1. The low refractive layer LRL may be configured to refract or totally reflect light according to an incident angle of the corresponding light. For example, the low refractive layer LRL may again provide light passing through the first light conversion pattern CCP1 to the first light conversion pattern CCP1. Accordingly, the light conversion efficiency of the first light conversion pattern CCP1 can be improved.

The color filter layer CFL may be disposed on the low refractive layer LRL. The color filter layer CFL may include the first color filter CF1 and light blocking patterns LBP. The first color filter CF1 may overlap the first light conversion pattern CCP1. The first color filter CF1 may allow light in a desired wavelength range to be selectively transmitted therethrough. In case that the first sub-pixel SP1 is a red sub-pixel, the first color filter CF1 may include a red color filter. The light blocking patterns LBP may include at least one of various kinds of light blocking materials.

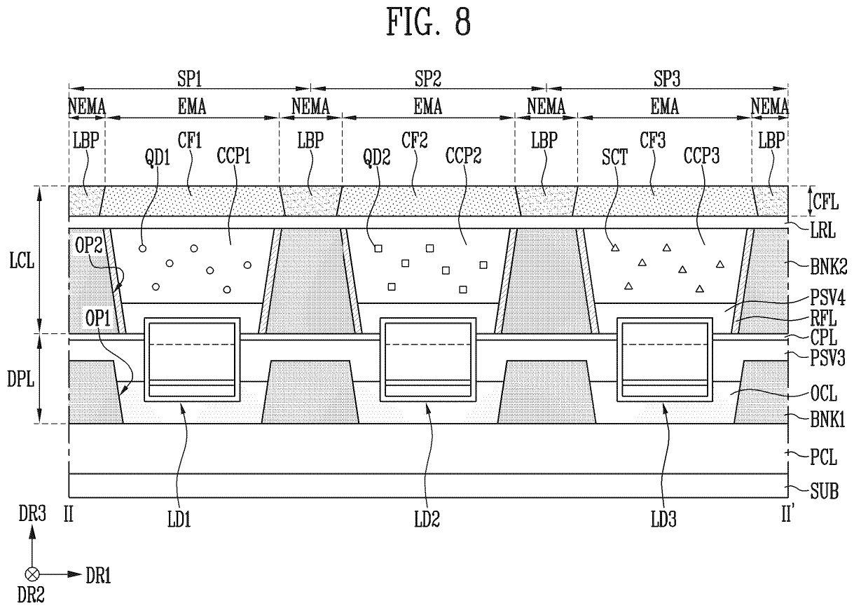

FIG. 8 is a schematic sectional view taken along line II-II′ shown in FIG. 6.

Referring to FIGS. 6 and 8, a pixel circuit layer PCL, a display panel layer DPL, and a light conversion layer LCL may be provided on a substrate SUB.

The pixel circuit layer PCL and the display panel layer DPL may be the same as described with reference to FIG. 7. In the pixel circuit layer PCL, sub-pixel circuits respectively corresponding to the first to third sub-pixels SP1 to SP3 may be provided. In the display panel layer DPL, first to third light emitting elements LD1 to LD3 respectively corresponding to the first to third sub-pixels SP1 to SP3 may be provided. The first to third light emitting elements LD1 to LD3 may overlap first openings OP1 of a first bank BNK1. The first light emitting element LD1 may be connected between a cathode electrode CE (see FIG. 7) and a transistor T_SP1 (see FIG. 7) included in a sub-pixel circuit of the first sub-pixel SP1. The second light emitting element LD2 may be connected between a cathode electrode CE and a transistor included in a sub-pixel circuit of the second sub-pixel SP2. The third light emitting element LD3 may be connected between the cathode electrode CE and a transistor included in a sub-pixel circuit of the third sub-pixel SP3. Hereinafter, redundant descriptions will be omitted.

The light conversion layer LCL may be provided on the display panel layer DPL. The light conversion layer LCL may be the same as described with reference to FIG. 7. Hereinafter, redundant descriptions will be omitted.

A second bank BNK2 may include second openings OP2. It may be understood that emission areas EMA and a non-emission area NEMA of the first to third sub-pixels SP1 to SP3 may be defined as the second bank BNK2. An area with which the second bank BNK2 overlaps may correspond to the non-emission area NEMA. Areas overlapping the second openings OP2 of the second bank BNK2 may correspond to the emission areas EMA of the first to third sub-pixels SP1 to SP3.

On a capping layer CPL, a fourth passivation layer PSV4 may be disposed in the second openings OP2. On the fourth passivation layer PSV4, first to third light conversion patterns CCP1 to CCP3 may be disposed in the second openings OP2.

In embodiments, the first to third light emitting elements LD1 to LD3 may be configured to emit light of a blue color. The first light conversion pattern CCP1 may include first color conversion particles QD1 configured to convert light of the blue color into light of a red color. The second light conversion pattern CCP2 may include second color conversion particles QD2 configured to convert light of the blue color into light of a green color. The third light conversion pattern CCP3 may include light scattering particles SCT which scatter light of the blue color so as to improve light emission efficiency. Accordingly, the first to third sub-pixels SP1 to SP3 may be provided as a red sub-pixel, a green sub-pixel, and a blue sub-pixel, respectively. In embodiments, at least one of the first to third light conversion patterns CCP1 to CCP3 may further include color conversion particles configured to convert light of the blue color into light of a white color.

In embodiments, the first to third light emitting elements LD1 to LD3 may be configured to emit lights of the red color, the green color, and the blue color, respectively. Each of the first to third light conversion patterns CCP1 to CCP3 may include light scattering particles SCT. As such, the particles included in the first to third light conversion patterns CCP1 to CCP3 may be variously changed according to the first to third light emitting elements LD1 to LD3.

In embodiments, the first to third light conversion patterns CCP1 to CCP3 may be omitted.

A low refractive layer LRL may be disposed on the second bank BNK2, a reflective layer RFL, and the first to third light conversion patterns CCP1 to CCP3. The low refractive layer LRL may have a refractive index lower than a refractive index of each of the first to third light conversion patterns CCP1 to CCP3 and first to third color filters CF1 to CF3. In embodiments, the low refractive layer LRL may be omitted in an area corresponding to the third sub-pixel SP3.

A color filter layer CFL may be disposed on the low refractive layer LRL. The color filter layer CFL may include the first to third color filters CF1 to CF3 and light blocking patterns LBP.

Each of the first to third color filters CF1 to CF3 may allow light in a desired wavelength range to be selectively transmitted therethrough. In case that the first sub-pixel SP1 is a red sub-pixel, the first color filter CF1 may include a red color filter. In case that the second sub-pixel SP2 is a green sub-pixel, the second color filter CF2 may include a green color filter. In case that the third sub-pixel SP3 is a blue sub-pixel, the third color filter CF3 may include a blue color filter.

The light blocking patterns LBP may be disposed between the color filters CF1 to CF3. It may be understood that the emission areas (or light emission areas) EMA and the non-emission area NEMA of the first to third sub-pixels SP1 to SP3 are defined by the light blocking patterns LBP. Areas corresponding to the light blocking patterns LBP may correspond to the non-emission area NEMA. Areas not overlapping the light blocking patterns LBP may correspond to the emission areas EMA.

In embodiments, the light blocking patterns LBP may include at least one of various kinds of light blocking materials. In embodiments, each of the light blocking patterns LBP may be provided in the form of a multi-layer overlapping at least two color filters among the first to third color filters CF1 to CF3. For example, each of the light blocking patterns LBP may be formed as the first to third color filters CF1 to CF3 overlap each other. In another example, a light blocking pattern LBP between the first and second color filters CF1 and CF2 among the light blocking patterns LBP may be formed as a multi-layer in which the first and second color filters CF1 and CF2 overlap, and a light blocking pattern LBP between the second and third color filters CF2 and CF3 among the light blocking patterns LBP may be formed as a multi-layer in which the second and third color filters CF2 and CF3 overlap. A light blocking pattern LBP between the first color filter CF1 and a third color filter CF3 of an adjacent pixel may be formed as a multi-layer in which the first and third color filters CF1 and CF3 overlap. As such, each of the first to third color filters CF1 to CF3 may extend to the non-emission area NEMA to form the light blocking patterns LBP.

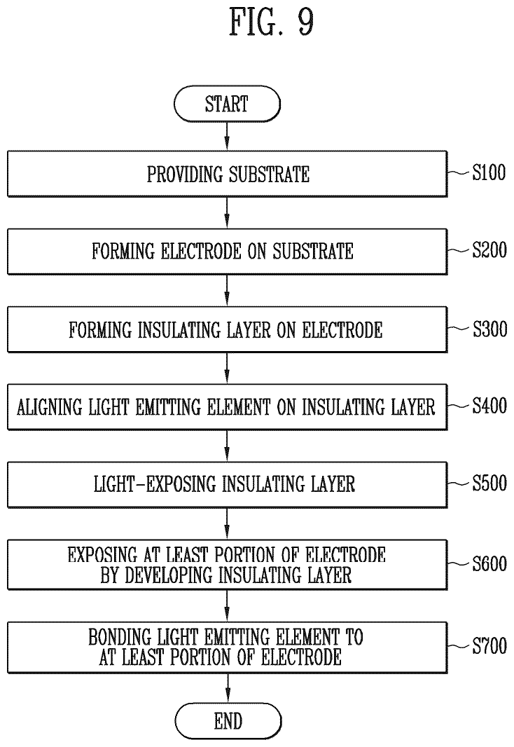

FIG. 9 schematically illustrates a method of manufacturing the display device in accordance with the embodiments of the disclosure.

Referring to FIG. 9, in the method of manufacturing the display device, a substrate may be provided (S100), an electrode may be formed on the substrate (S200), an insulating layer may be formed on the electrode (S300), a light emitting element may be aligned on the insulating layer (S400), the insulating layer may be light-exposed (S500), at least a portion of the electrode may be exposed by developing the insulating layer (S600), and the light emitting element may be bonded to the at least a portion of the electrode (S700).

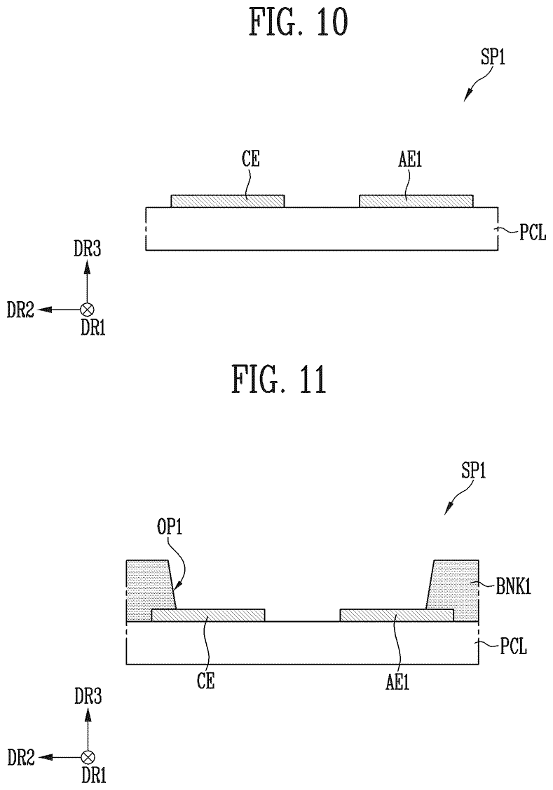

Hereinafter, such a method will be described in detail with reference to FIGS. 10 to 17.

FIGS. 10 to 17 are schematic views sequentially illustrating the method shown in FIG. 9.

For convenience of description, FIGS. 10 to 17 illustrate a first sub-pixel SP1, and each of the second and third sub-pixels SP2 and SP3 shown in FIG. 6 may also be formed identically to the first sub-pixel SP1 within a range in which it is not differently described herein.

Referring to FIG. 10, a cathode electrode CE and a first anode electrode AE1 may be formed on a pixel circuit layer PCL. The cathode electrode CE and the first anode electrode AE1 may be simultaneously or sequentially formed. In case that the cathode electrode CE and the first anode electrode AE1 are simultaneously formed, the cathode electrode CE and the first anode electrode AE1 may be patterned using the same mask. In case that the cathode electrode CE and the first anode electrode AE1 are sequentially formed, the cathode electrode CE and the first anode electrode AE1 may be patterned using different masks.

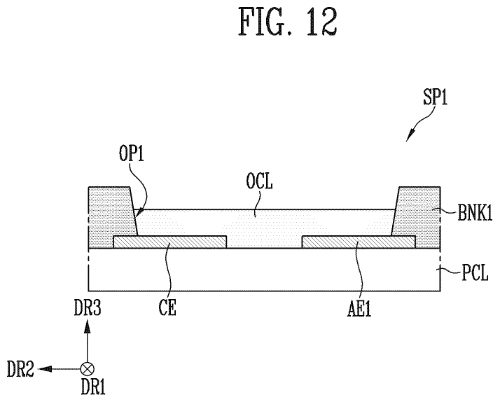

Referring to FIGS. 11 and 12, a first bank BNK1 may be formed on the cathode electrode CE and the first anode electrode AE1. For example, after the first bank BNK1 is entirely applied on the cathode electrode CE and the first anode electrode AE1, the first bank BNK1 may be etched to form a first opening OP1. An insulating layer OCL may be formed in the first opening OP1.

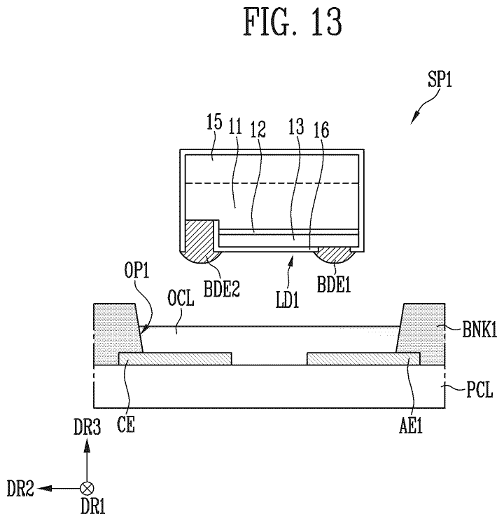

Referring to FIG. 13, a first light emitting element LD1 may be aligned on the insulating layer OCL. That is, the first light emitting element LD1 may be aligned in the first opening OP1 to overlap the cathode electrode CE and the first anode electrode AE1. For example, the first light emitting element LD1 may be aligned such that at least a portion of a first bonding electrode BDE1 overlaps the first anode electrode AE1. For example, the first light emitting element LD1 may be aligned such that at least a portion of a second bonding electrode BDE2 overlaps the cathode electrode CE.

The alignment refers to that the first light emitting element LD1 is located on a specific position (e.g., the insulating layer OCL) through an alignment apparatus. For example, the alignment apparatus may include an interposer. For example, the interposer may include polydimethylsiloxane (PDMS).

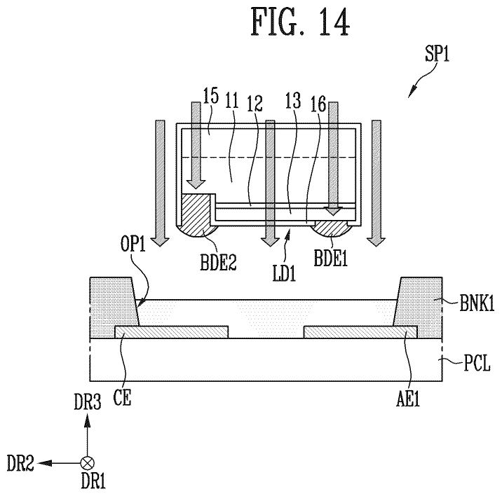

Referring to FIG. 14, the insulating layer OCL may be light-exposed by light irradiated on the first light emitting element LD1. For example, ultraviolet light may be irradiated toward the insulating layer OCL on the first light emitting element LD1.

The light irradiated toward the insulating layer OCL may be blocked by the first and second bonding electrodes BDE1 and BDE2. That is, the first and second bonding electrodes BDE1 and BDE2 may serve as a mask.

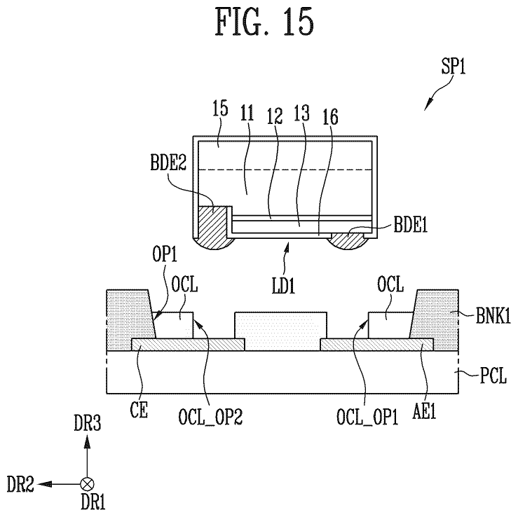

Referring to FIG. 15, the insulating layer OCL may be developed. As a result obtained by developing the insulating layer OCL, a first opening OCL_OP1 of the insulating layer OCL, which exposes the first anode electrode AE1, may be formed at a position corresponding to a position of the first bonding electrode BDE1, and a second opening OCL_OP2 of the insulating layer OCL, which exposes the cathode electrode CE, may be formed at a position corresponding to the second bonding electrode BDE2.

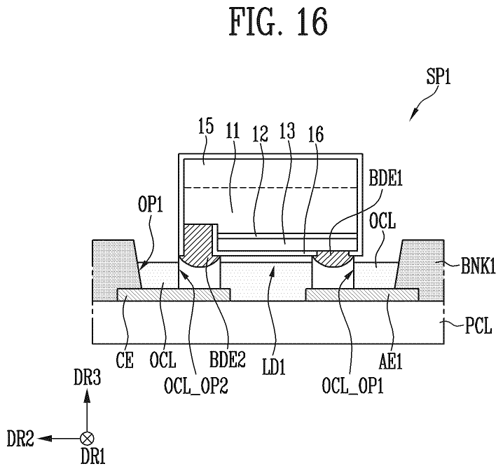

Referring to FIG. 16, the first bonding electrode BDE1 may be located in the first opening OCL_OP1 of the insulating layer OCL, and the second bonding electrode BDE2 may be located in the second opening OCL_OP2 of the insulating layer OCL. For example, a pressure may be applied in the opposite direction of the third direction DR3 to the first light emitting element LD1, and the first and second bonding electrodes BDE1 and BDE2 may be located in the first and second openings OCL_OP1 and OCL_OP2 of the insulating layer OCL. Empty spaces in which the first and second bonding electrodes BDE1 and BDE2 are to be filled by melting the first and second bonding electrodes BDE1 and BDE2 may be required between the first and second bonding electrodes BDE1 and BDE2 and the pixel circuit layer PCL.

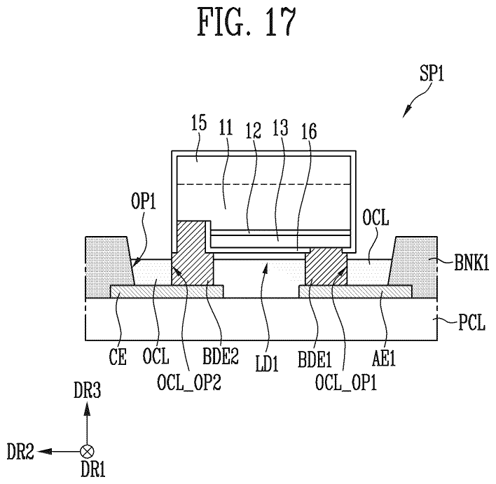

Referring to FIG. 17, in case that the first and second bonding electrodes BDE1 and BDE2 are located in the first and second openings OCL_OP1 and OCL_OP2 of the insulating layer OCL, heat may be applied to the first and second bonding electrodes BDE1 and BDE2, and the first and second bonding electrodes BDE1 and BDE2 may be melted. Accordingly, the first bonding electrode BDE1 may be bonded to the first anode electrode AE1, and the second bonding electrode BDE2 may be bonded to the cathode electrode CE.

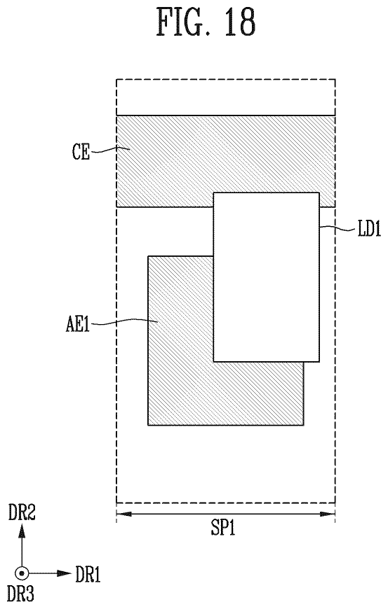

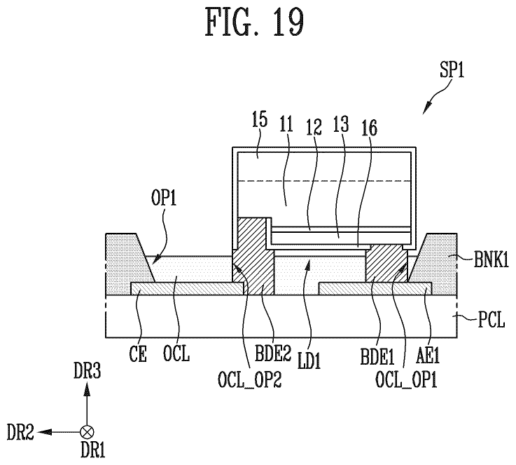

FIGS. 18 and 19 are schematic views illustrating that a first light emitting element is aligned at a dislocated position.

Referring to FIGS. 18 and 19, although the first light emitting element LD1 is aligned at a slightly dislocated position, the first light emitting element LD1 may be electrically connected to the first anode electrode AE1 and the cathode electrode CE. That is, since the first and second openings OCL_OP1 and OCL_OP2 of the insulating layer OCL are formed using the first light emitting element LD1 as a mask, the first light emitting element LD1 can be appropriately bonded to the first anode electrode AE1 and the cathode electrode CE even in case that the alignment of the first light emitting element LD1 is dislocated. Thus, a wider process tolerance can be secured.

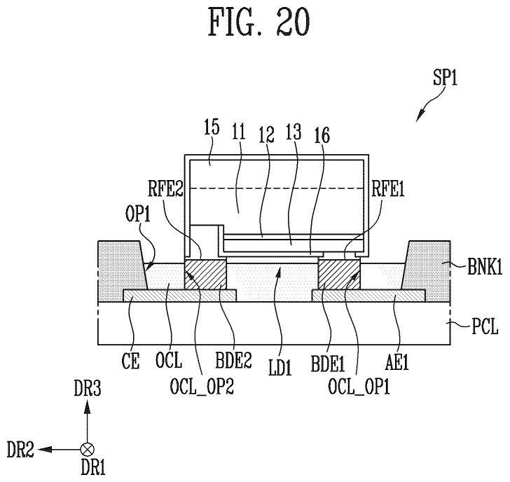

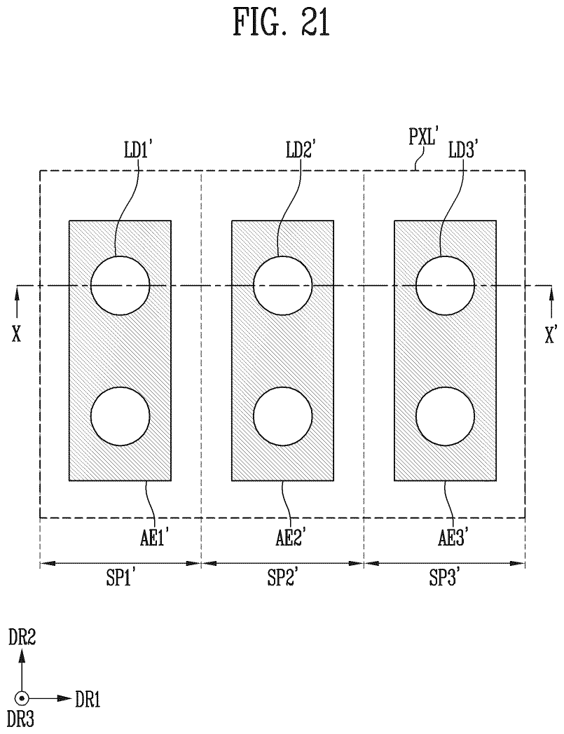

FIG. 20 is a schematic view illustrating that a first light emitting element of a display device is bonded in accordance with embodiments of the disclosure.

For convenience of description, FIG. 20 illustrates a first sub-pixel SP1, and each of the second and third sub-pixels SP2 and SP3 shown in FIG. 6 may also be formed identically to the first sub-pixel SP1 within a range in which it is not differently described herein.

The display device in accordance with the embodiments of the disclosure may be configured substantially identical to the display device DD shown in FIG. 1, except first and second reflective electrodes RFE1 and RFE2. Therefore, components identical or similar to those of the display device DD shown in FIG. 1 are designated by like reference numerals, and redundant descriptions will be omitted.

Referring to FIG. 20, a first light emitting element LD1 may include the first reflective electrode RFE1 disposed between a second semiconductor layer 13 and the first bonding electrode BDE1 and a second reflective electrode RFE2 disposed between a first semiconductor layer 11 and a second bonding electrode BDE2.

The first and second reflective electrodes RFE1 and RFE2 may include a conductive material suitable for reflecting light. Accordingly, the light emission efficiency of the first light emitting element LD1 can be improved. In embodiments, the first and second reflective electrodes RFE1 and RFE2 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

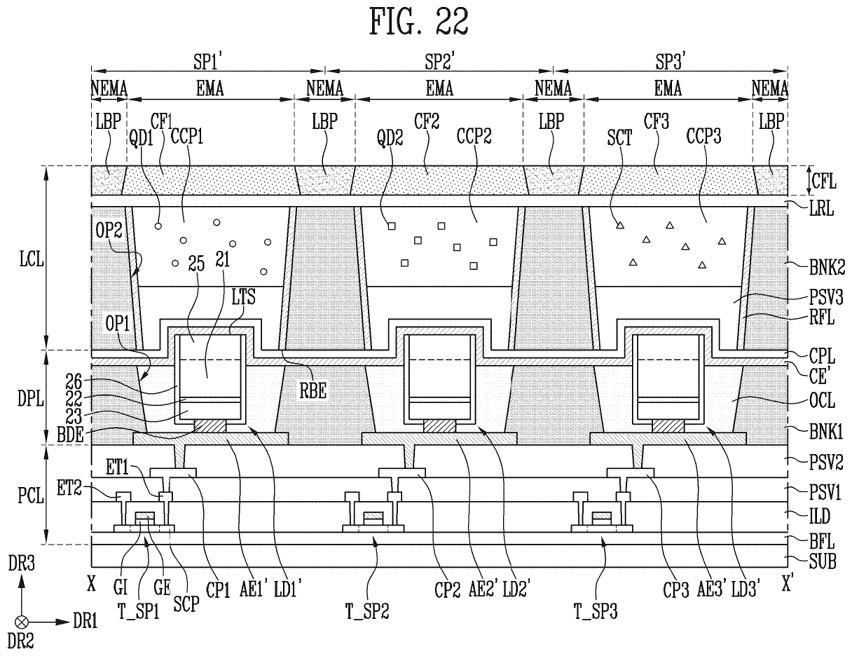

FIG. 21 is a schematic plan view illustrating a pixel of a display device in accordance with embodiments of the disclosure. FIG. 22 is a schematic sectional view taken along line X-X′ shown in FIG. 21.

The pixel PXL′ of the display device in accordance with the embodiments of the disclosure may be configured substantially identical to the pixel PXL of the display device shown in FIG. 6, except first to third light emitting elements LD1′, LD2′, and LD3′ and bonding thereof. Therefore, components identical or similar to those of the display device shown in FIG. 6 are designated by like reference numerals, and redundant descriptions will be omitted.

Referring to FIG. 21, the pixel PXL′ may include first to third sub-pixels SP1′ to SP3′. The first to third sub-pixels SP1′ to SP3′ may be arranged in the first direction DR1. However, the arrangement of the pixel PXL′ is not limited thereto, and may be variously changed in some embodiments. For example, the first to third sub-pixels SP1′ to SP3′ may be arranged in a zigzag form.

First to third anode electrodes AE1′ to AE3′ may be disposed in the first to third sub-pixels SP1′ to SP3′, respectively. The first anode electrode AE1′ may be provided as an anode electrode AE (see FIG. 2) connected to a sub-pixel circuit SPC (see FIG. 2) of the first sub-pixel SP1′. The second anode electrode AE2′ may be provided as an anode electrode AE connected to a sub-pixel circuit SPC of the second sub-pixel SP2′. The third anode electrode AE3′ may be provided as an anode electrode AE connected to a sub-pixel circuit SPC of the third sub-pixel SP3′.

One or more first light emitting elements LD1′, one or more second light emitting elements LD2′, and one or more third light emitting elements LD3′ may be disposed on the first to third anode electrodes AE1′ to AE3′. The first light emitting elements LD1′ may be connected to the first anode electrode AE1′. The second light emitting elements LD2′ may be connected to the second anode electrode AE2′. The third light emitting elements LD3′ may be connected to the third anode electrode AE3′. In case that multiple light emitting elements are provided in each sub-pixel, each anode electrode may have a shape extending in a specific direction such as the second direction DR2, and light emitting elements connected to the anode electrode may be arranged in the same direction.

The first light emitting elements LD1′ may be provided as the light emitting element LD shown in FIG. 2, which are included in the first sub-pixel SP1′. The second light emitting elements LD2′ may be provided as the light emitting element LD shown in FIG. 2, which are included in the second sub-pixel SP2′. The third light emitting elements LD3′ may be provided as the light emitting element LD shown in FIG. 2, which are included in the third sub-pixel SP3′. In case that multiple light emitting elements are provided in one sub-pixel, the light emitting elements may be connected in parallel between an anode electrode and a cathode electrode to be provided as the light emitting element LD shown in FIG. 2.

The first light emitting elements LD1′, the second light emitting elements LD2′, and the third light emitting elements LD3′ may be inorganic light emitting diodes including an inorganic light emitting material. However, embodiments are not limited thereto. For example, organic light emitting diodes may be used.

Referring to FIGS. 21 and 22, on a pixel circuit layer PCL, the first to third anode electrodes AE1′ to AE3′ may be disposed in the first to third sub-pixels SP1′ to SP3′, respectively.

The first anode electrode AE1′ may be electrically connected to a first connection electrode CP1 through a contact hole penetrating a second passivation layer PSV2. The second anode electrode AE2′ may be electrically connected to a second connection electrode CP2 through another contact hole penetrating the second passivation layer PSV2. The third anode electrode AE3′ may be electrically connected to a third connection electrode CP3 through still another contact hole penetrating the second passivation layer PSV2. As such, the first to third anode electrodes AE1′ to AE3′ may be electrically connected to first to third transistors T_SP1 to T_SP3, respectively.

A first bank BNK1 may be disposed on the first to third anode electrodes AE1′ to AE3′. The first bank BNK1 may have first openings OP1 exposing portions of the first to third anode electrodes AE1′ to AE3′. First to third light emitting elements LD1′ to LD3′ may be disposed in the first openings OP1 of the first bank BNK1. As such, the first bank BNK1 may be provided as a pixel defining layer defining areas in which the first to third light emitting elements LD1′ to LD3′ are located.

The first to third light emitting elements LD1′ to LD3′ may be disposed on the first to third anode electrodes AE1′ to AE3′, respectively. The first to third light emitting elements LD1′ to LD3′ may be bonded to the first to third anode electrodes AE1′ to AE3′, respectively.

The first light emitting element LD1′ may include a bonding electrode BDE, a first semiconductor layer 21, an active layer 22, a second semiconductor layer 23, and an auxiliary layer 25. The first light emitting element LD1′ may be implemented as a vertical light emitting stack structure in which the bonding electrode BDE, the second semiconductor layer 23, the active layer 22, the first semiconductor layer 21, and the auxiliary layer 25 are sequentially stacked on each other along the third direction DR3.

The first semiconductor layer 21 may be configured to provide electrons. The first semiconductor layer 21 may include, for example, at least one n-type semiconductor layer. For example, the first semiconductor layer 21 may include at least one semiconductor material among gallium nitride (GaN), aluminum gallium nitride (AlGaN), indium gallium nitride (InGaN), aluminum nitride (AlN), and indium nitride (InN), and be an n-type semiconductor layer doped with a first conductive dopant (or n-type dopant) such as silicon (Si), germanium (Ge) or tin (Sn). However, the material constituting the first semiconductor layer 21 is not limited thereto. Various materials may constitute the first semiconductor layer 21. In an embodiment of the disclosure, the first semiconductor layer 21 may include a gallium nitride (GaN) semiconductor material doped with the first conductive dopant (or n-type dopant). In some embodiments, the first semiconductor layer 21 along with the auxiliary layer 25 may constitute an n-type semiconductor layer.

The active layer 22 is disposed on the first semiconductor layer 21, and may be an area in which electrons and holes are recombined. As electrons and holes are recombined in the active layer 22, light may be generated, which has a level changed to a low energy level and has a wavelength corresponding to the low energy level. The active layer 22 may be formed in a single quantum well structure or a multi-quantum well structure. In case that the active layer 22 is formed in the multi-quantum well structure, a unit including a barrier layer, a strain reinforcing layer, and a well layer may be repeatedly stacked on each other, to form the active layer 22. However, embodiments of the active layer 22 are not limited thereto.

The second semiconductor layer 23 is disposed on the active layer 22, and provides holes to the active layer 22. The second semiconductor layer 23 may include a semiconductor layer of which type is different from the type of the first semiconductor layer 21. In an example, the second semiconductor layer 23 may include at least one p-type semiconductor layer. For example, the second semiconductor layer 23 may include at least one semiconductor material among gallium nitride (GaN), aluminum gallium nitride (AlGaN), indium gallium nitride (InGaN), aluminum nitride (AlN), and indium nitride (InN), and be a p-type semiconductor layer doped with a second conductive dopant (or p-type dopant) such as magnesium (Mg), zinc (Zn), calcium (Ca), strontium (Sr) or barium (Ba). However, the material constituting the second semiconductor layer 23 is not limited thereto. Various materials may constitute the second semiconductor layer 23. In an embodiment of the disclosure, the second semiconductor layer 23 may include a gallium nitride (GaN) semiconductor material doped with the second conductive dopant (or p-type dopant).

The bonding electrode BDE may be electrically connected to the second semiconductor layer 23. The bonding electrode BDE may include a eutectic metal.

The auxiliary layer 25 may include a gallium nitride (GaN) semiconductor material undoped with an impurity. The auxiliary layer 25 along with the first semiconductor layer 21 may constitute an n-type semiconductor layer.

The first light emitting element LD1′ may further include an insulative film 26 covering an outer circumferential surface of the vertical light emitting stack structure. The insulative film 26 may prevent an electrical short circuit which may occur while the active layer 22 is in contact with another conductive material except the first and second semiconductor layers 21 and 23. The insulative film 26 may include a transparent insulating material. The insulative film 26 may be configured to expose a bottom surface of the bonding electrode BDE, which is opposite to the second semiconductor layer 23. Also, the insulative film 26 may be configured to expose a top surface of the auxiliary layer 25, which is to be in contact with a cathode electrode CE′.

The bottom surface of the bonding electrode BDE may be in contact with the first anode electrode AE1′. The top surface of the auxiliary layer 25 may be connected to the cathode electrode CE′. Accordingly, the first light emitting element LD1′ may be electrically connected between the first anode electrode AE1′ and the cathode electrode CE′.

In embodiments, a reflective electrode may be disposed between the bonding electrode BDE and the second semiconductor layer 23. Light emitted from the first light emitting element LD1′ may be efficiently output toward a light conversion layer LCL. The reflective electrode may be configured with a conductive material having a predetermined or selected reflectivity. The conductive material may include an opaque metal. The opaque metal may include, for example, metals such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and alloys thereof. However, the material of the reflective electrode is not limited thereto.

Each of the second and third light emitting elements LD2′ and LD3′ may be configured identically to the first light emitting element LD1′. Hereinafter, redundant descriptions will be omitted.

The insulating layer OCL may be disposed in the first openings OP1 in which the first to third light emitting elements LD1′ to LD3′ are disposed. The insulating layer OCL may fix the first to third light emitting elements LD1′ to LD3′ bonded to the first to third anode electrodes AE1′ to AE3′ not to move. Also, the insulating layer OCL may protect components disposed thereunder from a foreign matter such as dust or moisture. For example, the insulating layer OCL may include at least one of an inorganic insulating layer and an organic insulating layer.

In embodiments, the insulating layer OCL may not be disposed on a top surface LTS of each of the first to third light emitting elements LD1′ to LD3′. The first to third light emitting elements LD1′ to LD3′ may protrude to the light conversion layer LCL. The first to third light emitting elements LD1′ to LD3′ may be at least partially located in second openings OP2 of a second bank BNK2. For example, a height of the top surface LTS of each of the first to third light emitting elements LD1′ to LD3′ from a substrate SUB may be higher than a height of a lowermost end RBE of a reflective layer RFL from the substrate SUB. Accordingly, light emitted from the first to third light emitting elements LD1′ to LD3′ may be provided to the light conversion layer LCL at a relatively high ratio.

The cathode electrode CE′ may be disposed on the first to third light emitting elements LD1′ to LD3′. The cathode electrode CE′ may be entirely disposed on the first bank BNK1, the first to third light emitting elements LD1′ to LD3′, and the insulating layer OCL. The cathode electrode CE′ may be in contact with an auxiliary layer 25 of each of the first to third light emitting elements LD1′ to LD3′. The cathode electrode CE′ may be electrically connected to the second power voltage node VSSN shown in FIG. 2. The second power voltage applied to the second power voltage node VSSN may be transferred to the first to third light emitting elements LD1′ to LD3′ through the cathode electrode CE′.

The cathode electrode CE′ may be substantially transparent or translucent to satisfy a predetermined or selected light transmittance. In embodiments, the cathode electrode CE′ may include at least one of various transparent conductive materials such as indium tin oxide (ITO), indium zinc oxide (IZO), zinc oxide (ZnO), indium gallium zinc oxide (IGZO), and indium tin zinc oxide (ITZO). However, the material of the cathode electrode CE′ is not limited thereto.

A capping layer CPL may be disposed over the cathode electrode CE′. The capping layer CPL may protect components disposed thereunder, such as the cathode electrode CE′ and the first to third light emitting elements LD1′ to LD3′, from external moisture, humidity, and the like. The capping layer CPL may include at least one of silicon nitride (SiNₓ), silicon oxide (SiOₓ), silicon oxynitride (SiOₓN_{y}), and a metal oxide such as aluminum oxide (AlOₓ). However, the material of the capping layer CPL is not limited thereto.

The light conversion layer LCL may be disposed on the capping layer CPL. The light conversion layer LCL may include the second bank BNK2, the reflective layer RFL, a third passivation layer PSV3, first to third light conversion patterns CCP1 to CCP3, a low refractive layer LRL, and a color filter layer CFL.

The second bank BNK2 may be disposed on the capping layer CPL. The second bank BNK2 may overlap the first bank BNK1. The second bank BNK2 may have the second openings OP2 overlapping the first openings OP1.

The second bank BNK2 may be configured to include a light blocking material, to prevent light mixture between adjacent sub-pixels and the first to third sub-pixels SP1′ to SP3′. In embodiments, the second bank BNK2 may include an organic material. For example, the second bank BNK2 may include an organic insulating material such as acrylic resin, epoxy resin, phenolic resin, polyamide resin, or polyimide resin.

The reflective layer RFL may be disposed on side surfaces of the second bank BNK2, which are adjacent to the second openings OP2. The reflective layer RFL may be configured to reflect incident light, and accordingly, light emission efficiency can be improved. The reflective layer RFL may include a material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

It may be understood that emission areas EMA and a non-emission area NEMA of the first to third sub-pixels SP1′ to SP3′ are defined by the second bank BNK2. An area which the second bank BNK2 overlaps may correspond to the non-emission area NEMA. Areas overlapping the second openings OP2 of the second bank BNK2 may correspond to the emission areas EMA.

On the capping layer CPL, the third passivation layer PSV3 may be disposed in the second openings OP2. The third passivation layer PSV3 may protect components disposed thereunder, and provide a flat top surface. The third passivation layer PSV3 may include the same material as any of first and second passivation layers PSV1 and PSV2, but embodiments are not limited thereto.

On the third passivation layer PSV3, the first to third light conversion patterns CCP1 to CCP3 may be disposed in the second openings OP2.

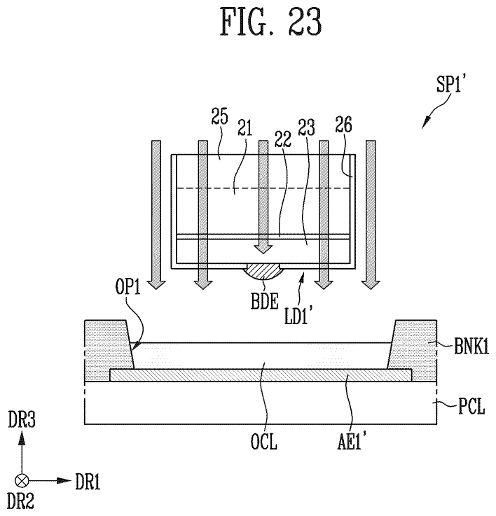

FIG. 23 is a schematic view illustrating that light exposure is performed to bond the first light emitting element shown in FIG. 21. A method of bonding the first light emitting element LD1′ shown in FIG. 21 may be substantially identical to the method described with reference to FIGS. 10 to 17, and therefore, redundant descriptions will be omitted.

Referring to FIG. 23, the insulating layer OCL may be light-exposed by light irradiated on the first light emitting element LD1′. For example, ultraviolet light may be irradiated toward the insulating layer OCL on the first light emitting element LD1.

The light irradiated toward the insulating layer OCL may be blocked by the bonding electrode BDE. That is, the bonding electrode BDE may serve as a mask.

As a result obtained by developing the insulating layer OCL, a first opening OCL_OP1 of the insulating layer OCL, which exposes the first anode electrode AE1′, may be formed at a position corresponding to the position of the bonding electrode BDE.

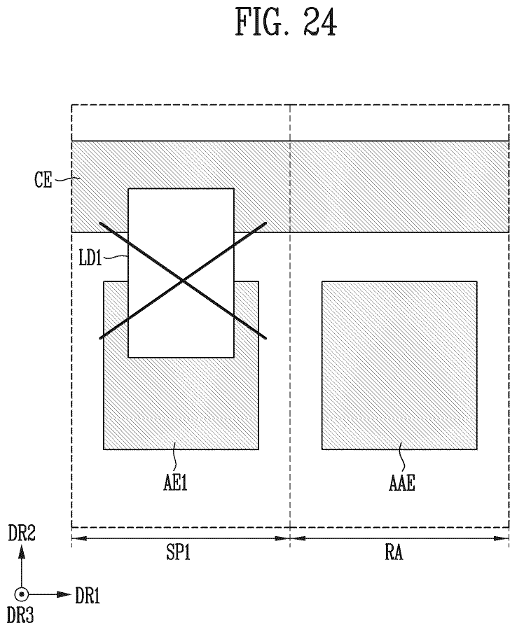

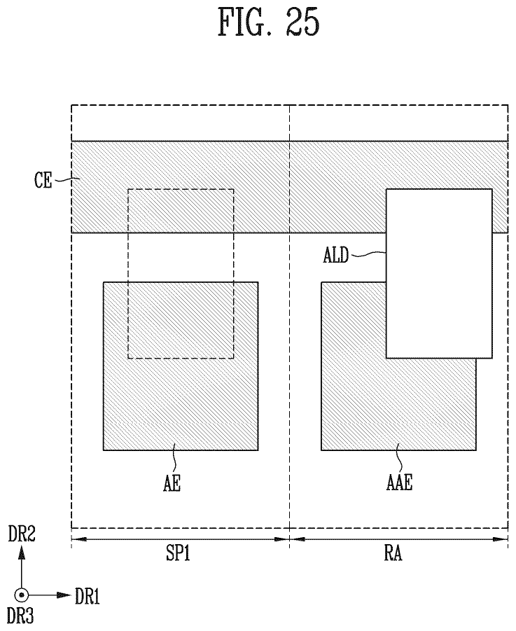

FIGS. 24 and 25 are schematic plan views illustrating a first sub-pixel of a display device and a repair area in accordance with embodiments of the disclosure.

A pixel of the display device in accordance with the embodiments of the disclosure may be configured substantially identical to the pixel PXL of the display device shown in FIG. 6, except a repair area RA. Therefore, components identical or similar to those of the display device shown in FIG. 6 are designated by like reference numerals, and redundant descriptions will be omitted.

Referring to FIGS. 24 and 25, in case that a first light emitting element LD1 has a defect, a light emitting element ALD (hereinafter, referred to as an additional light emitting element) may be bonded to an anode electrode AAE (hereinafter, referred to as an additional anode electrode) of the repair area RA adjacent to a first sub-pixel SP1. A structure of the repair area RA may be substantially identical to a structure of the first sub-pixel SP1.

The defect of the first light emitting element LD1 does not mean only a defect of the first light emitting element LD1 itself, but includes all defects that the first light emitting element LD1 does not normally emit light due to problems of bonding of the first light emitting element LD1, and the like.

The additional light emitting element ALD may be bonded substantially same as the first light emitting element LD1. For example, in case that the first light emitting element LD1 is determined as a defective light emitting element after the first light emitting element LD1 is bonded, the additional light emitting element ALD may be aligned in the repair area RA on the insulating layer OCL (see FIG. 8). At least a portion of the additional anode electrode AAE may be exposed as the insulating layer OCL (see FIG. 8) is light-exposed and developed, and the additional light emitting element ALD may be bonded to the additional anode electrode AAE.

As such, the additional light emitting element ALD may be used as a mask even in a process of bonding the additional light emitting element ALD, so that a process tolerance can be secured.

In the above, the repair area RA adjacent to the first sub-pixel SP1 has been described. Each of the second and third sub-pixels SP2 and SP3 shown in FIG. 6 may be configured identically to the first sub-pixel SP1 within a range in which it is not differently described herein. However, the repair area RA is not necessarily disposed for each of all sub-pixels.

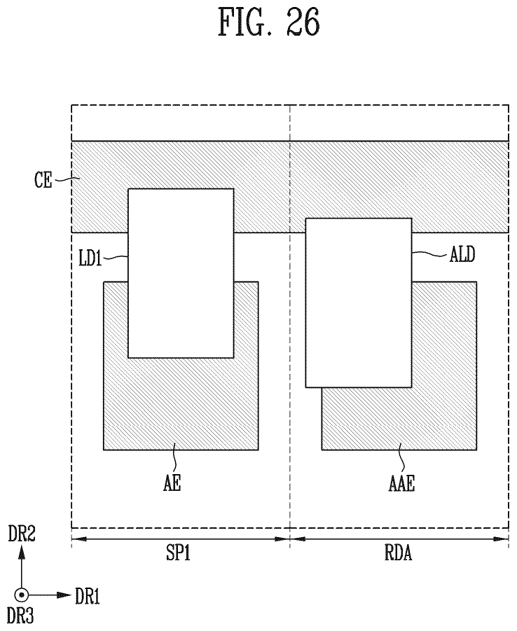

FIG. 26 is a schematic plan view illustrating a first sub-pixel of a display device and an overlapping area in accordance with embodiments of the disclosure.

A pixel of the display device in accordance with the embodiments of the disclosure may be configured substantially identical to the pixel PXL of the display device shown in FIG. 6, except an overlapping area RDA. Therefore, components identical or similar to those of the display device shown in FIG. 6 are designated by like reference numerals, and redundant descriptions will be omitted.

Referring to FIG. 26, a light emitting element ALD (hereinafter, referred to as an additional light emitting element) may be bonded to an anode electrode AAE (hereinafter, referred to as an additional anode electrode) of the overlapping area RDA adjacent to a first sub-pixel SP1. A structure of the overlapping area RDA may be substantially identical to a structure of the first sub-pixel SP1.

The additional light emitting element ALD may be bonded substantially same as the first light emitting element LD1. For example, after the first light emitting element LD1 is bonded, the additional light emitting element ALD may be aligned in the overlapping area RDA on the insulating layer OCL (see FIG. 8). At least a portion of the additional anode electrode AAE may be exposed as the insulating layer OCL (see FIG. 8) is light-exposed and developed, and the additional light emitting element ALD may be bonded to the additional anode electrode AAE.

The additional light emitting element ALD may operate in case that the first light emitting element LD1 becomes defective. For example, in case that the first light emitting element LD1 becomes defective while the display device is used, the additional light emitting element ALD may be driven in place of the first light emitting element LD1.

As such, the additional light emitting element ALD may be used as a mask even in a process of bonding the additional light emitting element ALD, so that a process tolerance can be secured.

In the above, the overlapping area RDA adjacent to the first sub-pixel SP1 has been described. Each of the second and third sub-pixels SP2 and SP3 shown in FIG. 6 may be configured identically to the first sub-pixel SP1 within a range in which it is not differently described herein. However, the overlapping area RDA is not necessarily disposed for each of all sub-pixels.

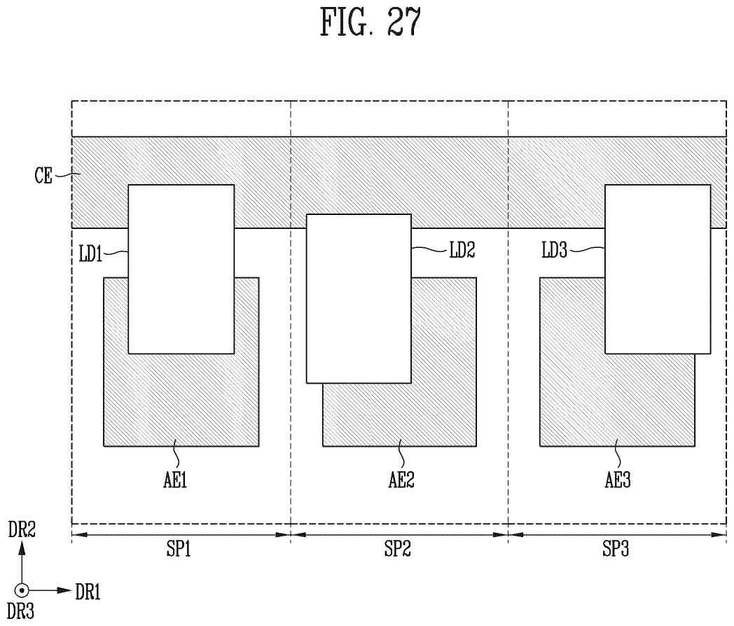

FIG. 27 is a schematic plan view illustrating an example in which the first to third light emitting elements are disposed in the pixel shown in FIG. 6.

Referring to FIG. 27, each of the first to third light emitting elements LD1 to LD3 may be bonded. For example, after the first light emitting element LD1 is bonded to the first anode electrode AE1 and the cathode electrode CE, the second light emitting element LD2 may be bonded to the second anode electrode AE2 and the cathode electrode CE. For example, after the second light emitting element LD2 is bonded to the second anode electrode AE2 and the cathode electrode CE, the third light emitting element LD3 may be bonded to the third anode electrode AE3 and the cathode electrode CE. However, the disclosure is not limited to an order in which the first to third light emitting elements LD1 to LD3 are bonded.

For example, in a method of manufacturing the display device, the first light emitting element LD1 may be aligned in the first sub-pixel SP1 on the insulating layer OCL (see FIG. 8), the insulating layer OCL (see FIG. 8) may be light-exposed, the first anode electrode AE1 and the cathode electrode CE may be exposed by developing the insulating layer OCL (see FIG. 8), the first light emitting element LD1 may be bonded to the first anode electrode AE1 and the cathode electrode CE, the second light emitting element LD2 may be aligned in the second sub-pixel SP2 on the insulating layer OCL (see FIG. 8), the insulating layer OCL (see FIG. 8) may be light-exposed, the second anode electrode AE2 and the cathode electrode CE may be exposed by developing the insulating layer OCL (see FIG. 8), the second light emitting element LD2 may be bonded to the second anode electrode AE2 and the cathode electrode CE, the third light emitting element LD3 may be aligned in the third sub-pixel SP3 on the insulating layer OCL (see FIG. 8), the insulating layer OCL (see FIG. 8) may be light-exposed, the third anode electrode AE3 and the cathode electrode CE may be exposed by developing the insulating layer OCL (see FIG. 8), and the third light emitting element LD3 may be bonded to the third anode electrode AE3 and the cathode electrode CE.

The first to third sub-pixels SP1 to SP3 mean a concept including even an area in which the first to third sub-pixels SP1 to SP3 are disposed.

As such, each of the first to third light emitting elements LD1 to LD3 is bonded, so that a process tolerance of each of the first to third light emitting elements LD1 to LD3 can be secured.

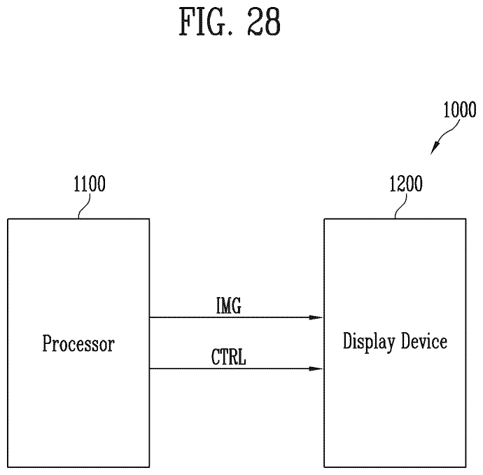

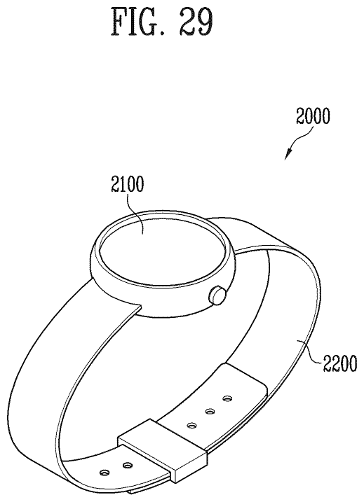

FIG. 28 is a schematic block diagram illustrating an embodiment of a display system.

Referring to FIG. 28, a display system 1000 may include a processor 1100 and a display device 1200.

The processor 1100 may perform various tasks and various calculations. In embodiments, the processor 1100 may include an Application Processor (AP), a Graphics Processing Unit (GPU), a microprocessor, a Central Processing Unit (CPU), and the like. The processor 1100 may be connected to other components of the display system 1000 through a bus system to control the components of the display system 1000.

The processor 1100 may transmit input image data IMG and a control signal CTRL to the display device 1200. The display device 1200 may display an image, based on the input image data IMG and the control signal CTRL. The display device 1200 may be configured identical to the display device DD described with reference to FIG. 1. The input image data IMG and the control signal CTRL may be provided as the input image data IMG and the control signal CTRL, which are shown in FIG. 1, respectively.

The display system 1000 may include a computing system for providing an image display function, such as a smart watch, a mobile phone, a smartphone, a portable computer, a tablet personal computer (PC), a watch phone, an automotive display, a smart glass, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

FIGS. 29 to 32 are schematic perspective views illustrating application examples of the display system shown in FIG. 28.

Referring to FIG. 29, the display system 1000 shown in FIG. 28 may be applied to a smart watch 2000 including a display part 2100 and a strap part 2200.

The smart watch 2000 may be a wearable electronic device. For example, the smart watch 2000 may have a structure in which the strap part 2200 is mounted on a wrist of a user. The display system 1000 and/or the display device 1200 may be applied to the display part 2100, so that image data including time information can be provided to the user.

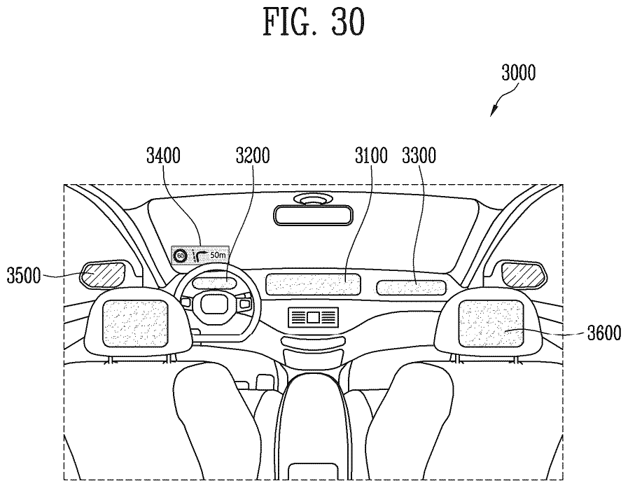

Referring to FIG. 30, the display system 1000 shown in FIG. 28 may be applied to an automotive display system 3000. The automotive display system 3000 may include a computing system provided at the inside/outside of a vehicle to provide image data.

For example, the display system 1000 and/or the display device 1200 may be applied to at least one of an infortainment panel 3100, a cluster 3200, a co-driver display 3300, a head-up display 3400, a side mirror display 3500, and a rear seat display 3600, which are provided in the vehicle.

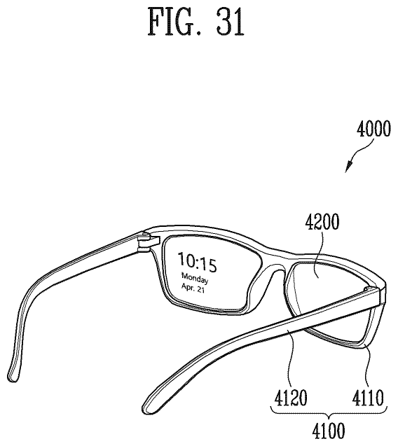

Referring to FIG. 31, the display system 1000 shown in FIG. 28 may be applied to smart glasses 4000. The smart glasses 4000 are a wearable electronic device which can be worn on the face of a user. For example, the smart glasses 4000 may be a wearable device for Augmented Reality (AR).

The smart glasses 4000 may include a frame 4100 and a lens part 4200. The frame 4100 may include a housing 4110 supporting the lens part 4200 and a leg part 4120 for allowing the user to wear the smart glasses 4000. The leg part 4120 may be connected to the housing 4110 through a hinge, to be folded or unfolded with respect to the housing 4110.

A battery, a touch pad, a microphone, a camera, and the like may be built in the frame 4100. A projector for outputting light, a processor for controlling a light signal, and the like may be built in the frame 4100.

The lens part 4200 may be an optical member which allows light to be transmitted therethrough or allows light to be reflected thereby. For example, the lens part 4200 may include glass, transparent synthetic resin, and the like.

In order to enable eyes of the user to recognize visual information, the lens part 4200 may allow an image caused by a light signal transmitted from the projector of the frame 4100 to be reflected by a rear surface (e.g., a surface in a direction facing the eyes of the user) of the lens part 4200. For example, the user may recognize information including time, data, and the like, which are displayed on the lens part 4200. The projector and/or the lens part 4200 may be a kind of display device. The display device 1200 may be applied to the projector and/or the lens part 4200.

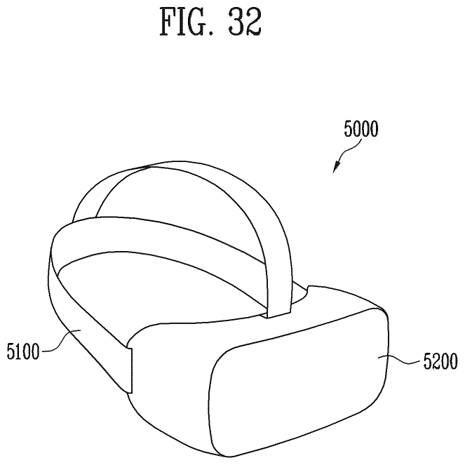

Referring to FIG. 32, the display system 1000 shown in FIG. 28 may be applied to a head mounted display device 5000.

The head mounted display device 5000 may be a wearable electronic device which can be worn on the head of a user. For example, the head mounted display device 5000 may be a wearable device for virtual reality (VR) or mixed reality (MR).

The head mounted display device 5000 may include a head mounted band 5100 and a display accommodating case 5200. The head mounted band 5100 may be connected to the display accommodating case 5200. The head mounted band 5100 may include a horizontal band and/or a vertical band, used to fix the head mounted display device 5000 to the head of the user. The horizontal band may be configured to surround a side portion of the head of the user, and the vertical band may be configured to surround an upper portion of the head of the user. However, embodiments are not limited thereto. For example, the head mounted band 5100 may be implemented in the form of a glasses frame, a helmet or the like.

The display device accommodating case 5200 may accommodate the display system 1000 and/or the display device 1200.

The disclosure can be applied to display devices and electronic devices including the same. For example, the disclosure can be applied to digital TVs, 3D TVs, mobile phones, smart phones, tablet computers, VR devices, PCs, home appliances, notebook computers, PDAs, PMPs, digital cameras, music players, portable game consoles, navigation systems, and the like.

In the method of manufacturing the display device in accordance with the disclosure, a light emitting element is used as a mask, so that a process tolerance can be secured. Accordingly, the yield of the display device can be improved.

In the method of manufacturing the display device in accordance with the disclosure, a light emitting element is used as a mask, so that the number of masks can be decreased. Accordingly, processes can be simplified.

In the method of manufacturing the display device in accordance with the disclosure, an insulating layer is formed on an anode electrode and/or a cathode electrode, and an opening is formed using a light emitting element as a mask, so that a short circuit between the cathode electrode and the anode electrode can be prevented.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure.

What is claimed is:

1. A method of manufacturing a display device, the method comprising:
forming a first electrode on a substrate;
forming an insulating layer over the first electrode;
aligning a first light emitting element on the insulating layer;
light-exposing the insulating layer;
exposing at least a portion of the first electrode by developing the insulating layer; and
bonding the first light emitting element to the at least a portion of the first electrode.

2. The method of claim 1, wherein the first light emitting element includes a first bonding electrode bonded to the at least a portion of the first electrode.

3. The method of claim 2, wherein the first light emitting element further includes:
a semiconductor layer; and
a reflective electrode disposed between the semiconductor layer and the first bonding electrode.

4. The method of claim 2, wherein the bonding of the first light emitting element includes:
locating the first bonding electrode in an opening of the insulating layer, which exposes the at least a portion of the first electrode; and
melting the first bonding electrode.

5. The method of claim 2, wherein an opening of the insulating layer, which exposes the at least a portion of the first electrode, is formed at a position corresponding to a position of the first bonding electrode.

6. The method of claim 1, wherein
a second electrode spaced apart from the first electrode is formed in the forming of the first electrode,
at least a portion of the second electrode is exposed in the developing of the insulating layer, and
the first light emitting element is bonded to the at least a portion of the first electrode and the at least a portion of the second electrode.

7. The method of claim 6, wherein the first light emitting element includes a second bonding electrode bonded to the at least a portion of the second electrode.

8. The method of claim 1, wherein the insulating layer includes a photosensitive organic insulating material.

9. The method of claim 1, wherein
the first light emitting element is bonded to the first electrode of a first sub-pixel, and
the method further comprises bonding an additional light emitting element to the first electrode of a repair area adjacent to the first sub-pixel in case that the first light emitting element is defective.

10. The method of claim 9, wherein the bonding of the additional light emitting element includes:
aligning the additional light emitting element in the repair area on the insulating layer;
light-exposing the insulating layer;
exposing at least a portion of the first electrode of the repair area by developing the insulating layer; and
bonding the additional light emitting element to the at least a portion of the first electrode of the repair area.

11. The method of claim 1, wherein
the first light emitting element is bonded to the first electrode of a first sub-pixel, and
the method further comprises bonding an additional light emitting element to the first electrode of an overlapping area adjacent to the first sub-pixel.

12. The method of claim 11, wherein the additional light emitting element is driven in case that the first light emitting element becomes defective.

13. The method of claim 1, wherein
the first light emitting element is bonded to the first electrode of a first sub-pixel, and
the method further comprises:
aligning a second light emitting element in a second sub-pixel on the insulating layer;
repeating the light-exposing of the insulating layer;
exposing at least a portion of the first electrode of the second sub-pixel by re-developing the insulating layer; and
bonding the second light emitting element to the at least a portion of the first electrode of the second sub-pixel.

14. The method of claim 13, wherein the first sub-pixel and the second sub-pixel display different colors.

15. A method of bonding a light emitting element, the method comprising:
aligning a light emitting element on an insulating layer formed over an electrode;
light-exposing the insulating layer;
exposing at least a portion of the electrode by developing the insulating layer; and
bonding the light emitting element to the at least a portion of the electrode.

16. The method of claim 15, wherein the light emitting element includes a bonding electrode bonded to the at least a portion of the electrode.

17. The method of claim 16, wherein the bonding of the light emitting element includes:
locating the bonding electrode in an opening of the insulating layer, which exposes the at least a portion of the electrode; and
melting the bonding electrode.

18. The method of claim 16, wherein an opening of the insulating layer, which exposes the at least a portion of the electrode, is formed at a position corresponding to a position of the bonding electrode.

19. The method of claim 16, wherein the light emitting element further includes:
a semiconductor layer; and
a reflective electrode disposed between the semiconductor layer and the bonding electrode.

20. The method of claim 15, wherein the insulating layer includes a photosensitive organic insulating material.
